(19) United States
(12) Patent Application Publication
(10) Pub. No.: US 2026/0113060 A1
(43) Pub. Date: Apr. 23, 2026

(54) METHODS, SYSTEMS, AND APPARATUS FOR ENCODED BIT REDUCTION IN POLAR CODING

(71) Applicant: Huawei Technologies Co., Ltd., Shenzhen (CN)

(72) Inventors: Huazi Zhang, Hangzhou (CN); Jun Wang, Hangzhou (CN); Wen Tong, Ottawa (CA)

(21) Appl. No.: 19/335,944

(22) Filed: Sep. 22, 2025

Related U.S. Application Data
(63) Continuation of application No. PCT/CN2023/083345, filed on Mar. 23, 2023.

(51) Int. Cl. H03M 13/13; H03M 13/27

(52) U.S. Cl. CPC H03M 13/13; H03M 13/27

(57) ABSTRACT

Polar codes for wireless communications are constructed to adapt to channel conditions. Input bits are encoded by a polar code to obtain a number of encoded bits, and a reduced number of the encoded bits are decoded to obtain decoded input bits. The polar code provides or includes bit indices for bit values, and the bit indices include a first set of bit indices for values of the input bits and a second set of bit indices for a predetermined bit value. Encoded bits in a subset, which includes fewer than all of the encoded bits and is for reducing the number of the encoded bits, are interleaved.

### CROSS-REFERENCE TO RELATED APPLICATION

The present application is a continuation of International Application No. PCT/CN2023/083345, entitled “METHODS, SYSTEMS, AND APPARATUS FOR ENCODED BIT REDUCTION IN POLAR CODING” and filed on Mar. 23, 2023, the disclosure of which is hereby incorporated by reference in its entirety.

### TECHNICAL FIELD

The present application relates to coding, and in particular to reducing a number of encoded bits in polar coding.

### BACKGROUND

In wireless communications, channel conditions are constantly changing at both fast and slow scale due to, for example, fading effects. Accordingly, channel coding has conventionally always been designed to adapt to channel conditions. Modulation and coding scheme (MCS) adaptation, in which the modulation order, code length, and code rate can be changed in real time, is a powerful approach to combat varying channel conditions.

Adapting to channel conditions requires use of channel coding that can flexibly change code length and code rate in a fine-grained way, and at the same time achieve good error correction performance in all possible configurations. This fine-grained flexibility of channel codes remains a challenge.

Probabilistic codes such as low density parity check (LDPC) codes, which are more like random codes, may be naturally suited for flexibility. However, algebraic codes such as Reed-Muller (RM) codes and Bose-Chaudhuri-Hocquenghem (BCH) codes, are not as flexible as probabilistic codes. This is because their inherent coding structures may be compromised when code length or rate changes. Polar codes exhibit features from both probabilistic codes and algebraic codes. As a result, polar codes have a level of flexibility that lies between probabilistic codes and algebraic codes.

Rate matching, including techniques such as puncturing and shortening, is techniques for implementing rate-compatible polar codes, such as the polar codes used in the fifth generation (5G) new radio (NR) 3GPP standard. However, the degree of flexibility afforded by conventional approaches to polar code rate matching is insufficient for supporting more advanced communications features, such as fine-grained incremental-redundancy hybrid automatic repeat request (IR-HARQ), for example.

A more flexible channel coding approach is needed.

### SUMMARY

The present disclosure encompasses embodiments related to partially interleaved encoded bit reduction, by rate matching for example, in polar coding. Some embodiments may also or instead involve a form of adaptive assignment of bits to subchannels or bit positions for encoding, referred to herein primarily as information bit recycling. These embodiments and features as disclosed herein may be useful, for example, in providing rate-compatible polar codes with good performance.

According to an aspect of the present disclosure, a method involves encoding input bits by a polar code to obtain a number of encoded bits, interleaving a subset of the encoded bits, and outputting a reduced number of the encoded bits. The polar code comprises a plurality of bit indices for placing values of the input bits before encoding, and the bit indices include a first set of bit indices for the values of the input bits, and a second set of bit indices for a predetermined bit value. The subset includes fewer than all of the encoded bits, and is for reducing the number of the encoded bits.

Another method involves encoding input bits by a polar code to obtain a number of encoded bits and outputting a reduced number of the encoded bits. The polar code comprises a plurality of bit indices for placing values of the input bits before encoding, and the bit indices comprise a first set of bit indices for the values of the input bits, and a second set of bit indices for a predetermined bit value. The encoded bits comprise a subset including fewer than all of the encoded bits, and the subset is for reducing the number of the encoded bits. The bit indices comprise a respective first bit index on which a value of a respective input bit is placed instead of the value of the respective input bit being placed on a respective second bit index that corresponds to a bit index of each encoded bit in the subset.

A method according to another aspect of the present disclosure involves obtaining an ordered sequence indicating a plurality of bit indices for a polar code in an order of rank for placing values of input bits for encoding by the polar code to obtain a number of encoded bits; encoding the input bits by the polar code according to the ordered sequence, to obtain the number of encoded bits; and outputting the reduced number of the encoded bits. The bit indices comprise: a first set of bit indices of highest rank according to the ordered sequence, for placing the values of the input bits before encoding; and a second set of bit indices of lower rank than the highest rank according to the ordered sequence, for placing a predetermined bit value. The order of rank is for reducing the number of the encoded bits.

The present disclosure also encompasses a method that involves receiving a reduced number of encoded bits encoded by a polar code, and decoding the reduced number of encoded bits to obtain decoded input bits. The polar code comprises a plurality of bit indices for placing values of input bits, and the bit indices comprise a first set of bit indices for the values of the input bits, and a second set of bit indices for a predetermined bit value. The received reduced number of encoded bits comprises bits of the encoded bits that remain after reduction in a number of the encoded bits in an interleaved subset of fewer than all of the encoded bits.

Yet another method involves: receiving a reduced number of encoded bits encoded by a polar code, the polar code comprising a plurality of bit indices for placing values of input bits, the bit indices comprising a first set of bit indices for the values of the input bits, and a second set of bit indices for a predetermined bit value; and decoding the reduced number of encoded bits to obtain decoded input bits. The received reduced number of encoded bits comprise bits of the encoded bits that remain after reduction in a number of the encoded bits in a subset of the encoded bits that includes fewer than all of the encoded bits. The bit indices comprise a respective first bit index on which a value of a respective input bit was placed instead of the value of the respective input bit being placed on a respective second bit index that corresponds to a bit index of each encoded bit in the subset.

According to another aspect of the present disclosure, a method involves receiving a reduced number of encoded bits encoded by a polar code, and decoding the reduced number of encoded bits to obtain decoded input bits. The polar code comprises a plurality of bit indices for placing values of input bits for encoding to obtain a number of encoded bits, and the bit indices comprise: a first set of bit indices of highest rank according to an ordered sequence, for placing values of the input bits before encoding; and a second set of bit indices of lower rank than the highest rank according to the ordered sequence, for placing a predetermined bit value. The ordered sequence indicates the plurality of bit indices in an order of rank for placing the values of the input bits, and the order of rank is for reducing the number of the encoded bits to the reduced number of the encoded bits.

Apparatus embodiments are also disclosed.

An apparatus may include an encoder, an interleaver, and an interface. The encoder is for encoding input bits by a polar code to obtain a number of encoded bits. The polar code comprises a plurality of bit indices for placing values of the input bits before encoding, and the bit indices comprise a first set of bit indices for the values of the input bits, and a second set of bit indices for a predetermined bit value. The interleaver is coupled to the encoder, for interleaving a subset of the encoded bits. The subset includes fewer than all of the encoded bits, and is for reducing the number of the encoded bits. The interface is coupled to the encoder, for outputting the reduced number of the encoded bits.

Another apparatus embodiment includes an encoder and an interface. The encoder is for encoding input bits by a polar code to obtain a number of encoded bits. As in other embodiments, the polar code comprises a plurality of bit indices for placing values of the input bits before encoding, and the bit indices comprise a first set of bit indices for the values of the input bits, and a second set of bit indices for a predetermined bit value. The encoded bits comprise a subset including fewer than all of the encoded bits, and the subset is for reducing the number of the encoded bits. The bit indices comprise a respective first bit index on which a value of a respective input bit is placed instead of the value of the respective input bit being placed on a respective second bit index that corresponds to a bit index of each encoded bit in the subset. The interface is coupled to the encoder, for outputting the reduced number of the encoded bits.

An apparatus according to another aspect of the present disclosure includes an encoder and an interface. The encoder is for obtaining an ordered sequence and encoding input bits by a polar code according to the ordered sequence, to obtain a number of encoded bits. The ordered sequence indicates a plurality of bit indices for the polar code in an order of rank for placing values of the input bits for the encoding by the polar code to obtain the number of encoded bits. The bit indices comprise: a first set of bit indices of highest rank according to the ordered sequence, for placing the values of the input bits before encoding; and a second set of bit indices of lower rank than the highest rank according to the ordered sequence, for placing a predetermined bit value. The order of rank is for reducing the number of the encoded bits. The interface is coupled to the encoder, for outputting the reduced number of the encoded bits.

An apparatus may include an interface and a decoder. The interface is for receiving a reduced number of encoded bits encoded by a polar code. The polar code comprises a plurality of bit indices for placing values of input bits, and the bit indices comprise a first set of bit indices for the values of the input bits, and a second set of bit indices for a predetermined bit value. The received reduced number of encoded bits comprise bits of the encoded bits that remain after reduction in a number of the encoded bits in an interleaved subset of fewer than all of the encoded bits. The decoder is coupled to the interface, for decoding the reduced number of encoded bits to obtain decoded input bits.

According to yet another aspect, an apparatus includes an interface for receiving a reduced number of encoded bits encoded by a polar code. The polar code comprises a plurality of bit indices for placing values of input bits, and the bit indices comprise a first set of bit indices for the values of the input bits, and a second set of bit indices for a predetermined bit value. The received reduced number of encoded bits comprise bits of the encoded bits that remain after reduction in a number of the encoded bits in a subset of the encoded bits that includes fewer than all of the encoded bits. The bit indices comprise a respective first bit index on which a value of a respective input bit was placed instead of the value of the respective input bit being placed on a respective second bit index that corresponds to a bit index of each encoded bit in the subset. Such an apparatus may also include a decoder coupled to the interface, for decoding the reduced number of encoded bits to obtain decoded input bits.

Another apparatus includes an interface for receiving a reduced number of encoded bits encoded by a polar code. The polar code comprises a plurality of bit indices for placing values of input bits for encoding to obtain a number of encoded bits, and the bit indices comprise: a first set of bit indices of highest rank according to an ordered sequence, for placing values of the input bits before encoding; and a second set of bit indices of lower rank than the highest rank according to the ordered sequence, for placing a predetermined bit value. The ordered sequence indicates the plurality of bit indices in an order of rank for placing the values of the input bits, and the order of rank is for reducing the number of the encoded bits to the reduced number of the encoded bits. An apparatus may also include a decoder coupled to the interface, for decoding the reduced number of encoded bits to obtain decoded input bits.

In other apparatus embodiments, an apparatus may include a processor configured to cause the apparatus to perform a method as disclosed herein.

An apparatus may include a processor and a non-transitory computer readable storage medium that is coupled to the processor and stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

A system is also disclosed, and may include a first communication device and a second communication device. The first communication device is configured to transmit a reduced number of encoded bits that have been encoded by a polar code. The polar code comprises a plurality of bit indices for placing values of input bits, and the bit indices comprise a first set of bit indices for the values of the input bits, and a second set of bit indices for a predetermined bit value. The reduced number of encoded bits comprise bits of the encoded bits that remain after reduction in a number of the encoded bits in an interleaved subset of fewer than all of the encoded bits. The second communication device is configured to receive the reduced number of the encoded bits from the first communication device, and to decode the reduced number of the encoded bits to obtain decoded input bits.

System embodiments may include communication devices that perform, implement, support, or enable any of the other features disclosed herein.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a trellis graph illustrating an example of a polar code.

FIG. 6 is a diagram illustrating puncturing and shortening with a cyclic buffer.

FIG. 7 is a diagram illustrating partial interleaving and puncturing according to an embodiment.

FIG. 8 is a diagram illustrating partial interleaving and puncturing according to another embodiment.

FIG. 9 is a diagram illustrating partial interleaving and puncturing according to yet another embodiment.

FIG. 10 is a diagram illustrating partial interleaving and puncturing according to an embodiment with multiple different interleavers.

FIG. 11 is a diagram illustrating row-by-row writing and column-by-column reading to interleave partial code bits according to an embodiment.

FIG. 12 is a diagram illustrating punctured and transmitted information sets in a partially interleaved codeword.

FIG. 13 is a diagram illustrating information bit copying from a punctured information set to a transmitted information set according to an embodiment.

FIG. 14 includes trellis graphs illustrating information bit recycling according to an embodiment.

FIG. 15 includes trellis graphs illustrating information bit recycling and partial interleaving according to an embodiment.

FIG. 16 includes trellis graphs illustrating more aggressive information bit recycling and partial interleaving according to an embodiment.

FIG. 17 is a flow diagram illustrating more general example methods according to embodiments.

FIG. 18 is a block diagram illustrating an apparatus according to an embodiment.

### DETAILED DESCRIPTION

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

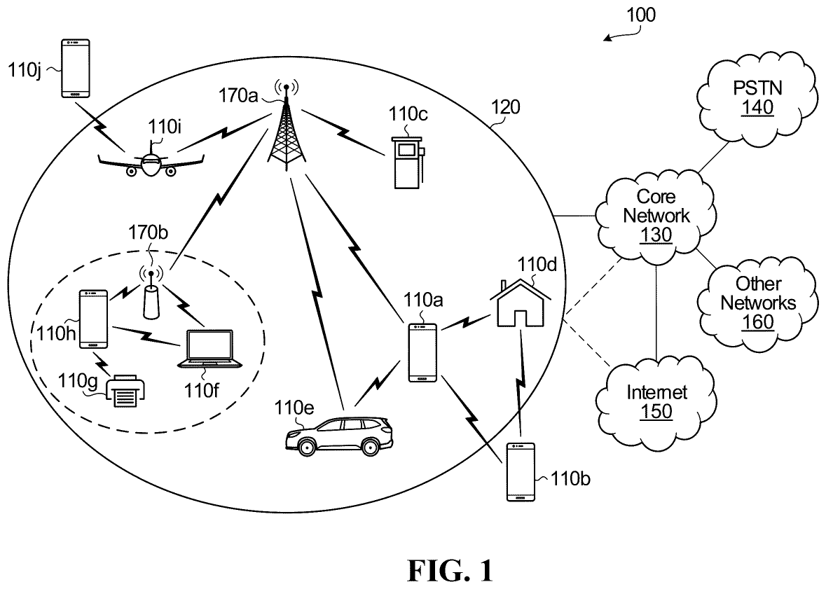

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

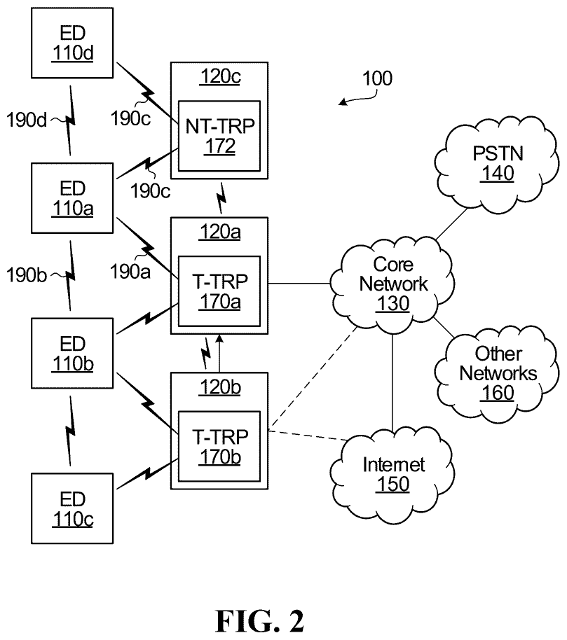

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 175 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

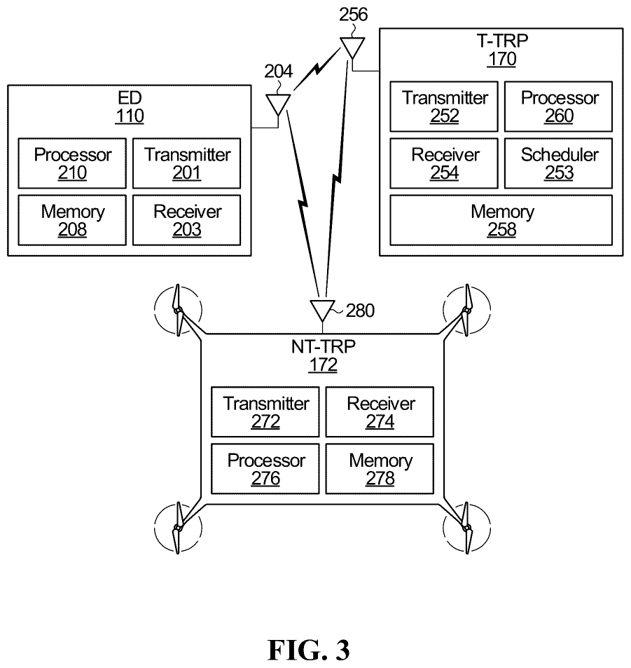

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IoT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g., communication module, modem, or chip) in the forgoing devices, among other possibilities. Future generation EDs 110 may be referred to using other terms. The base stations 170a and 170b each T-TRPs and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., the in memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses antennas 256 for the T-TRP 170, and may be coupled to the equipment that houses antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

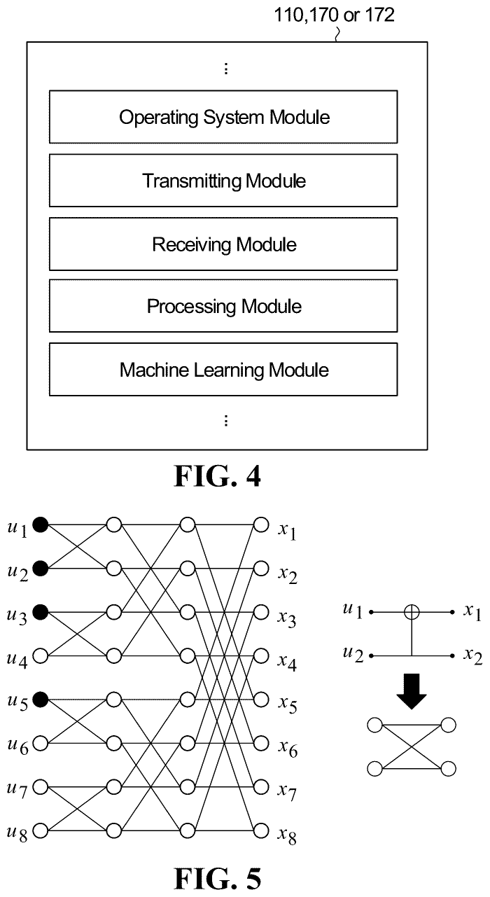

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

Having considered communications more generally above, attention will now turn to particular example embodiments.

Successive cancellation (SC) is the basic decoding algorithm for polar codes. In SC decoding, all frozen bits and information bits are decoded sequentially, bit by bit, according to a defined decoding order of the polar code. By convention, the decoding order is the natural order of the polar code bit indices on which all frozen bits and information bits are placed. Thus, this conventional decoding order is known as “natural order”. Preceding bits of the natural order are always decoded first, before decoding a current bit.

Successive cancellation list (SCL) is an enhanced decoding algorithm for polar codes, where multiple (L) SC decoding instances are executed. Each instance is called a “decoding path”. When decoding each binary bit, both “0” and “1” branches are extended to each path, creating 2L paths. Then, all 2L paths are compared, where the most likely L paths are kept, and the least likely L paths are discarded (or pruned). The path extension and pruning operations are performed during decoding every information bit, until all information bits are decoded. At last, the most likely path is selected as the decoding output.

CRC-aided successive cancellation list (CA-SCL) decoding works almost the same as SCL, except that in the last step, the most likely path that passes CRC check is selected as the decoding output.

Parity-check successive cancellation list (PC-SCL) decoding also works almost the same as SCL, except that when decoding parity-check (PC) bits, the parity check value of associated preceding bits is used as a bit decision result. In code construction, PC bits are generated in addition to frozen bits and information bits.

Polar codes are linear block codes. For a polar code of length N, its generator matrix is G_{N}, and its encoding process is

$${x}_{1}^{N} = {u}_{1}^{N} {G}_{N} ,$$

where

$${u}_{1}^{N} = [ {u}_{1} , {u}_{2} , ... , {u}_{N} ]$$

and is a binary input vector, and

$${x}_{1}^{N} = [ {x}_{1} , {x}_{2} , ... , {x}_{N} ]$$

and is a binary code vector. The N×N binary generator matrix is

$${G}_{N} = {F}_{2}^{⊗ n} ,$$

where

$${F}_{2} = [ \begin{matrix}1 & 0 \\ 1 & 1\end{matrix} ]$$

and is the polarization kernel matrix (also known as the Arikan kernel or Arikan matrix), ⊗ represents a Kronecker product, and n=log₂ N.

With K information bits to be encoded into N code bits and K<N, a code rate of R=K/N<1 is obtained. This implies only part of

$${u}_{1}^{N}$$

is used to carry information bits, and the remining bits of

$${u}_{1}^{N}$$

are typically set to a fixed value and are known as frozen bits. The information bit set (or information set) may be denoted by I, and the frozen bit set (or frozen set) may be denoted by F. Sometimes, there is an additional PC bit set, denoted by P. The frozen bits are known and usually set to all zeros before decoding, so they do not carry any information. The PC bits are parity-check bits of a subset of information bits, and therefore are known once the associated information bits are decoded. Decoding of polar codes attempts to recover all information bits.

Code length M may, but might not always, be a power of 2, in which case M<N. In practice, puncturing and shortening are used to reduce the number of transmitted code bits from N to M. For convenience, N is referred to as mother code length, and M is referred to as code length herein. In particular, punctured bits of the mother code are untransmitted bits that are unknown to a decoder, but shortened bits are untransmitted bits that are known to the decoder (usually all zeros).

FIG. 5 is a trellis graph illustrating an example of a polar code with N=8 and K=4. Each “butterfly” in the graph is a polarization, and one butterfly is shown by way of example at the right in FIG. 5, for

$${x}_{1}^{2} = {u}_{1}^{2} [ \begin{matrix}1 & 0 \\ 1 & 1\end{matrix} ] .$$

In the example shown, the unshaded circles at the left represent the information set I={u₄, u₆, u₇, u₈}, and the shaded circles represent the frozen set F={u₁, u₂, u₃, u₅}.

The input vector u at the left in FIG. 5 and the code vector x at the right in FIG. 5 each include a number of bit positions. The bit positions in the input vector are indexed by respective bit indices, and bit values are placed on or at those bit indices or bit positions for encoding. These bit indices or bit positions are also sometimes referred to as bit channels or subchannels. Placing bit values on bit indices as disclosed herein may also be referred to in other ways, such as placing bits or bit values on or at bit indices, bit positions, bit channels, or subchannels; or assigning bit values or bits to bit indices, bit positions, bit channels, or subchannels. Other terminology may be used to express how bit values or bits are provided as inputs to encoding.

In this way, a polar code may be considered as providing or comprising bit indices, bit positions, bit channels, or subchannels for bit values. Those bit indices, bit positions, bit channels, or subchannels are not necessarily only for bits that are to be encoded. For example, the u vector elements u₁, . . . u_{N} are also referenced in decoding, and therefore bit values that are decoded may similarly be associated with bit indices, bit positions, bit channels, or subchannels.

On the right side in FIG. 5, the code vector x also includes a number of elements that are in or at bit positions or bit indices. A bit value on the i-th bit index in the input vector u has some effect on multiple code bits in the code vector x, but the bit value on the i-th bit index in the input vector u is the primary contributor to the value of the code bit on the corresponding i-th bit index in the code vector x. In this sense, for a polar code, input vector bit indices or bit positions may be considered to correspond to, or be associated with or related to, code vector bit indices or bit positions. This is the case for polar codes, and there may be different input/code bit correspondence, relationships, or associations for other types of codes.

Regarding encoding, the process of encoding may be expressed in any of various ways. For example, encoding may be described as encoding bits to obtain encoded bits or to generate encoded bits. The above-referenced encoding processing

$${x}_{1}^{N} = {u}_{1}^{N} {G}_{N} ,$$

for example, may be expressed as generating or otherwise obtaining an encoding input (the input vector u in this example) that includes bits or bit values for encoding, to obtain or generate a number of encoded bits (the code vector x in this example).

The bit values of elements in the input vector u, from an encoding perspective, may be referred to as values or bits to be encoded, or as values or bits for encoding, for example. Blocks of bits or bit values for encoding are also sometimes referred to as code blocks. The bit values of elements in the code vector x may be referred to as encoded bits, coded bits, or code bits, and a block of such bits may be referred to as a codeword, for example.

From a decoding perspective, decoding may be referred to as decoding encoded bits, a codeword, or a code, or as decoding, obtaining, or recovering bits or bit values (that were encoded), from the encoded bits, a codeword, or a code, for example. The bit values of elements in the vector u, in the context of decoding, may be referred to as decoded or recovered bits or bit values.

Rate-compatible polar coding is a key technology for wireless applications.

A technique called quasi-uniform puncturing (QUP) has been proposed (see K. Niu, K. Chen and J. R. Lin, “Beyond turbo codes: Rate-compatible punctured polar codes,” 2013 IEEE International Conference on Communications (ICC), 2013, pp. 3423-3427, doi: 10.1109/ICC.2013.6655078), in which the reliabilities of all the polarized subchannels are calculated according to the puncturing pattern by a density evolution using a Gaussian approximation (DE/GA). Consider the construction of a punctured polar code of length M and information length K from a mother polar code of length N=2ⁿ. The puncturing pattern P of size N-M is chosen to be the first N-M bits of the code word. The information set I of size K and frozen set F of size N-K is determined by DE/GA, tracking the mean values of log-likelihood ratios (LLRs) or L-densities.

According to this approach, a design SNR (cSNR) is selected by initializing a puncturing vector

$${q}_{1}^{N}$$

such that positions in the puncturing pattern (punctured positions) are ones, and other positions are zeros. The reliability of each synthesized channel is calculated using DE/GA, which involves many floating-point computations that are hardware-intensive. The frozen set Fis determined as the set of the N-K indices of the synthesized channels with the lowest reliabilities.

Although QUP rate matching has very good performance and involves only puncturing, its implementation complexity is very high due to the DE/GA computations required for determining channel reliabilities. Alternatively, if pre-defined information/frozen sets are used to avoid that complexity, then performance may suffer catastrophically.

In 5G NR, a combination of puncturing, shortening and repetition is used together with a fixed reliability sequence to balance performance and complexity. See 3rd Generation Partnership Project (3GPP), “Multiplexing and channel coding,” 3GPP 38.212 V.15.3.0, 2018. More importantly, no DE/GA scheme is involved. In particular, a subblock-wise interleaving, which may also be referred to as interlacing, is used for both puncturing and shortening. The puncturing and shortening patterns are complementary and, together, form a symmetric (with respect to a polar code sequence) rate matching scheme.

With mother code length N, and code length M, the specific rate matching scheme used in 5G NR is as follows:
Repetition, when M>N;
Puncturing, when K/M≤7/16;
Shortening, when K/M>7/16.

A subblock-wise interleaving is performed before puncturing and shortening. An interleaver partitions the length-N mother code into 32 subblocks of size N/32 and interleaves them. Puncturing is performed from the first bit of a codeword, also referred to herein as a code bit, a coded bit, or an encoded bit, and shortening is performed from the last code bit. A rate matching module is efficiently implemented through a cyclic buffer. All mother code bits are placed in the cyclic buffer, puncturing is done by selecting the bits in clockwise order, and shortening is done by selecting bits in counter-clockwise order.

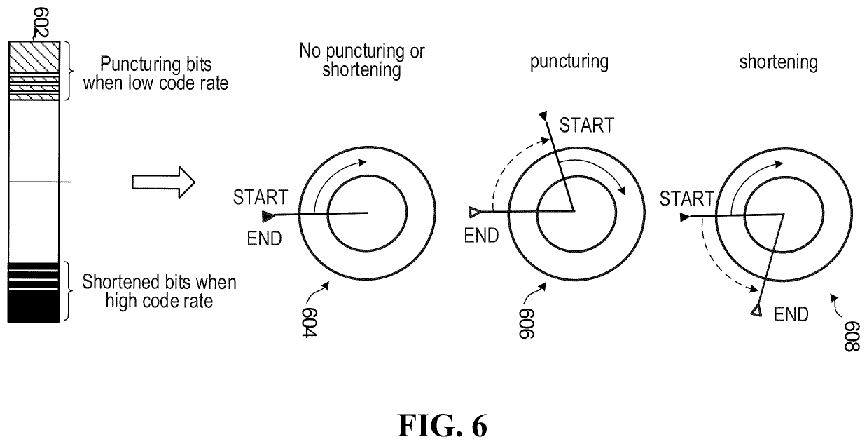

FIG. 6 is a diagram illustrating puncturing and shortening with a cyclic buffer. At 602 in FIG. 6, code bits of a codeword are illustrated in a vertical column, with punctured and shortened bits as shown. At 604, FIG. 6 illustrates a cyclic buffer, represented by a circle shape, and reading of code bits with no puncturing or shortening. The next two circles illustrate, respectively, cyclic buffers with dashed lines representing puncturing from the beginning of the buffer at 606 and shortening from the end of the buffer at 608.

These existing rate matching schemes for polar codes can achieve some flexibility. However, they have several drawbacks.

For example, the puncture-only technique described above requires complex online (i.e., real-time) calculations (DE/GA), and others may only be applicable for very low code rates.

The current 5G NR rate matching approach has many shortened bits, which are known at the receiver and thus cannot be transmitted for carrying additional information about source bits when code length needs to be increased. This drawback reduces the flexibility of the 5G NR rate matching scheme.

This approach also uses a combination of puncturing and shortening, and selection of puncturing or shortening is based on code rate. This rate-dependent rate matching incurs additional hardware logic and therefore slows down both encoding and decoding.

Another potential issue with the examples provided above is that there are many frozen bits in current PC polar codes. These frozen bits are typically set to zero (or another known value), and do not carry any information, which impacts code performance.

Some embodiments disclosed herein are directed to addressing a technical problem related to providing more flexible rate-compatible polar codes. 5G NR has adopted a rate-dependent rate matching scheme, but its flexibility may be undermined at least in part by shortening, and the adopted approach has relatively high implementation complexity. In some embodiments, puncturing is preferred over hybrid puncturing and shortening. Rate compatibility as disclosed herein involves, in some embodiments, operations or features before the polar transformation in polar coding, which can provide more flexibility on how to use code bits, rather than after the polar transformation.

Disclosed embodiments may also or instead be relevant to a technical problem of avoiding catastrophic performance loss in puncture-only schemes. If the computationally intractable DE/GA scheme is not used, then puncture-only rate matching may provide an advantage of low-complexity hardware implementation. However, there may still be a challenge for this type of rate matching for medium and high rate codes (R>1/3). Some embodiments not only avoid DE/GA computations, but still have good performance at medium and high rate codes.

The present disclosure encompasses embodiments that involve a partially interleaved puncturing pattern, or equivalently a partially interleaved transmission pattern. A flexible and fine-grained partial interleaving pattern may be supported by a parameterized configuration and/or parameter-based description.

An approach referred to herein primarily as information bit recycling is used in some embodiments to determine information/frozen sets, and thus placement of bit values on bit indices, for polar coding.

In embodiments of the present disclosure, partial interleaving refers to interleaving only part of a codeword, rather than an entire codeword, which may also be referred to as a code vector, denoted by c. The code bits in a codeword c may be divided into two parts c₀ and c₁, for example. Parts may also or instead be referred to as subsets, blocks, or portions, for example, and “subset” is used herein to generally refer to parts, blocks, or portions of encoded bits or a codeword, that include fewer than all of the encoded bits of a codeword. In this example there are two subsets c₀ and c₁, but there may be more than two subsets in general.

Partial interleaving, in this context of dividing code bits of a codeword into two subsets, means that one of those subsets is not interleaved (at least not interleaved for the purpose of rate matching) and the other is interleaved. For ease of reference, suppose that c₀ is not interleaved, and c₁ is interleaved. Rate matching is then performed, and the partially interleaved codeword is rate matched, by puncturing for example, for code length M<N, and P=N-M bits are punctured in this example. Puncturing is performed from the interleaved part.

Interleaving, as used herein in the context of disclosed embodiments, refers to changing an order of elements of a subset. Interleaving is used primarily herein, but is intended to encompass such changing of order more generally, and may also or instead be referred to as shuffling, reordering, scrambling, interlacing, interweaving, etc. An interleaved subset includes the same elements as a subset before interleaving, but in a different order within the subset.

One potential benefit of reducing a number of encoded bits, by rate matching such as puncturing, is to allocate capacity to a whole codeword. Bit indices that correspond to encoded bits that are punctured have zero capacity, and bit indices that correspond to transmitted encoded bits have a capacity that depends on signal to noise ratio (SNR).

Partial interleaving, combined with reducing the number of encoded bits, can provide for more accurate allocation of capacity to where it is needed the most. For subsets of encoded bits of a codeword in which the number of encoded bits is not reduced, there is no need for interleaving. Full interleaving (e.g., as implemented in 5G NR) will change the order of all encoded bits, and therefore puncturing will, in effect, apply to an entire codeword because an encoded bit that was originally at any position in a codeword may appear at a puncture position after interleaving. More targeted reduction in the number of encoded bits, by puncturing or otherwise, is preferable such that encoded bits are removed from only certain parts of a codeword, and accordingly only certain bit indices or parts of a code block have reduced capacity. Other codeword and code block parts are not adversely impacted, or at least are not adversely impacted as significantly. Put another way, only certain parts of a code or codeword are punctured, and it is preferable to restrict interleaving to those parts.

To summarize, a potential advantage of partial interleaving compared to interleaving all encoded bits is enabling more targeted and fine-tuned encoded bit reduction, such as via puncturing for example. Disclosed embodiments may also provide for lower description and implementation complexity as well.

For the length of the interleaved subset(s) of a codeword, there are several options. For example, with a proportion of the interleaved subset(s) with respect to the current mother code length of c denoted by ε, ε can be a parameter that is configured by a communication standard or specification, or through control signaling such as downlink control information (DCI) and/or uplink control information (UCI) signaling.

In some embodiments, ε is 1/X, where X is a power of 2. This type of reciprocal power of 2 value of the parameter & may be preferred where mother code length is a power of 2, so that the resulting proportional length of a subset of encoded bits and the reduced number of encoded bits after puncturing will more easily form a shorter polar code.

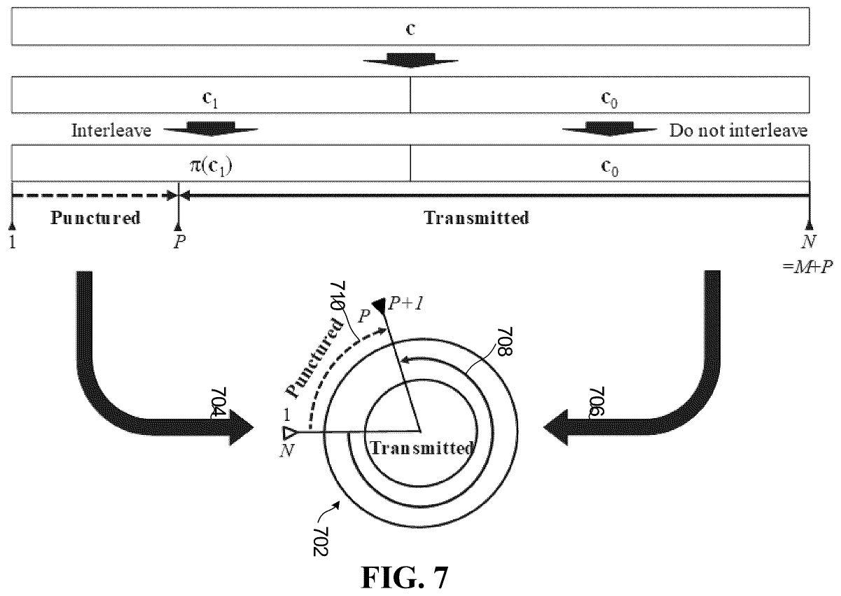

Regarding the position(s) of the interleaved subset(s) within a codeword, in an embodiment the subsets are evenly distributed within the codeword. FIG. 7 is a block diagram illustrating partial interleaving and puncturing according to such an embodiment.

With reference to FIG. 7, in the case of two equal-length subsets of encoded bits in a codeword, the two subsets c₁ and c₀ may be the first and second halves of the codeword c as shown. With codeword c of length N, c₁=c[1, 2 . . . . N/2] and c₀=c[N/2+1, N/2+2 . . . . N]. The interleaved subsets may be denoted by π(c₁), and is concatenated with the non-interleaved subset, c₀ in this example, to generate a partially interleaved codeword c′=[π(c₁), c₀].

In practice, the bits in c′ can be sequentially written into a cyclic buffer. In FIG. 7, a cyclic buffer is shown at 702, and the arrows 704, 706 are intended to represent sequentially writing π(c₁) and c₀ into the cyclic buffer. Transmission starts at the N-th bit, and proceeds counter-clockwise in the sense of the circular buffer to the (P+1)-th bit, and is illustrated by the arrow 708 in the example shown. Equivalently, transmission may start at the (P+1)-th bit, and proceed clockwise in the sense of the circular buffer 708 to the N-th bit. As a result, the 1^{st} to the P-th bits of the interleaved codeword part π(c₁) are not transmitted, which means that those bits are punctured. Puncturing is illustrated in FIG. 7 by the dashed arrow 710.

In FIG. 7, c₁ is an example of a subset of encoded bits, in codeword c. The subset includes fewer than all of the encoded bits in c. The encoded bits in the subset c₁ are interleaved, and the number of encoded bits in the interleaved subset π(c₁) is reduced, by puncturing in the example shown. Thus, the subset c₁ is, in at least this sense, for reducing the number of encoded bits. The reduced number of encoded bits may be output, for transmission for example.

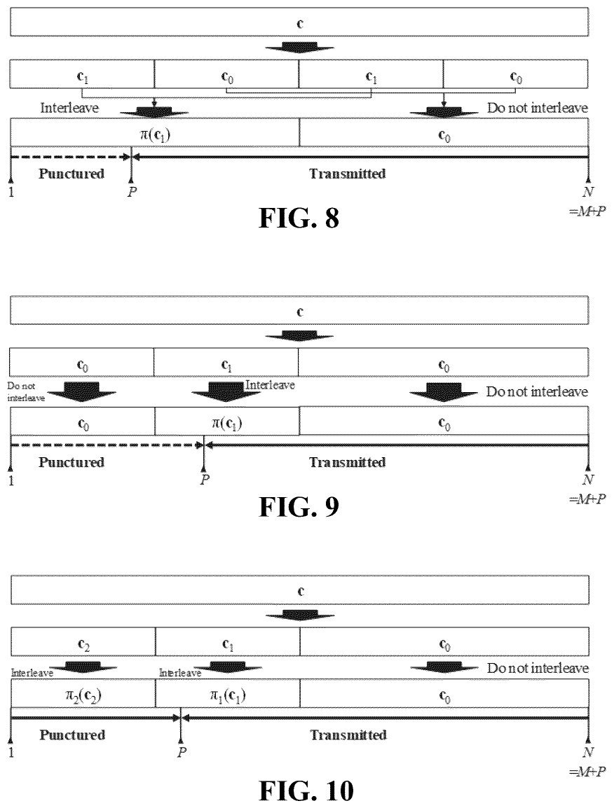

FIG. 8 is a block diagram illustrating partial interleaving and puncturing according to another embodiment, in which subset c₁, which is to be interleaved, is partially “sandwiched” between encoded bits in non-interleaved subset c₀. This illustrates that codeword subsets such as c₀ and c₁ need not necessarily be consecutive or serial, and may instead be interspersed with each other within a codeword c.

The example shown in FIG. 8 is illustrative of an embodiment in which a codeword c is divided or partitioned into S shorter blocks. In some embodiments, the number of shorter blocks S is a power of 2, which may be preferred where mother code length is a power of 2 so that the length of an interleaved codeword subset and the reduced number of encoded bits remaining after puncturing will more easily form a shorter polar code. Equal-length shorter blocks may also be preferred for the same reasons.

One or more of the shorter blocks, including two shorter blocks in the example shown, are selected for interleaving, and the other shorter blocks will not be interleaved. In the case of one shorter block being selected for interleaving, the shorter block is a subset of encoded bits for interleaving. Multiple shorter blocks selected for interleaving may be aggregated into a subset and interleaved, and the interleaved subset may be moved to the front of a partially interleaved codeword, or the shorter blocks may remain in their original positions in a codeword but with their encoded bits in interleaved order. In the example shown in FIG. 8, S=4, and the 1^{st} and 3^{rd} shorter blocks are selected and aggregated into a subset for interleaving, and moved to the front of the partially interleaved codeword c′=[π(c₁), c₀]. The example in FIG. 8 is illustrative of a subset that includes encoded bits that are non-consecutive in the order of encoded bits in a codeword.

FIG. 9 is a block diagram illustrating partial interleaving and puncturing according to yet another embodiment, in which the encoded bits to be interleaved (in a codeword subset c₁) are selected, inserted, or otherwise positioned or “sandwiched” between encoded bits in c₀. Here c₁ is interleaved, but stays in its original position. The example in FIG. 9 is illustrative of a subset that is preceded by and followed by other encoded bits in the order of encoded bits in a codeword.

Interleaving is not in any way restricted to a single interleaver or type of interleaving. For example, multiple interleavers may be used to separately interleave multiple subsets of encoded bits of a codeword. This feature enables design of finer-grained puncturing patterns, which may help better adapt to different code rates and lengths.

Consider a code vector c being divided into multiple subsets c₀, c₁, c₂ . . . c_{B}, where B is the number of subsets. Partial interleaving means that only one or more of the subsets, but not all of the subsets, are separately interleaved, with other subset(s) and encoded bits of the codeword remaining non-interleaved.

FIG. 10 is a block diagram illustrating partial interleaving and puncturing according to such an embodiment, with multiple different interleavers. In FIG. 10, the codeword c is divided into B=3 subsets, denoted by c₀, c₁, c₂, and subsets c₁, c₂ are interleaved in two different interleavers: π₁ and π₂. The interleaved subsets are π₁(c₁) and π₂(c₂), respectively, and c₀ is not interleaved, and the partially interleaved codeword is a concatenation of π(c₂), π₂(c₁), and c₀. This is illustrative of an embodiment in which there are multiple unique subsets, which include fewer than all of the encoded bits, to be interleaved. In such an embodiment, the subsets to be interleaved together also include fewer than all of the encoded bits, so that the interleaving remains partial interleaving even though multiple subsets of encoded bits are interleaved.

Different types of interleaving are also possible. Multiple types of interleavers or interleaving can be supported for partial interleaving, and several illustrative examples are described herein.

In block interleaving, original code bits are written into and read from a block interleaver with RI rows (referring to the number of rows of the interleaver, RI) and CI columns (referring to the number of columns of the interleaver, CI). Either or both row-in write/column-out read and column-in write/row-out read may be supported.

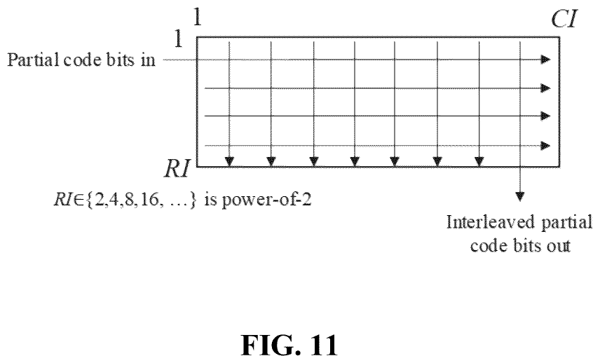

Without loss of generality, partial code bits, which are the encoded bits that are to be interleaved, may be written row-by-row and read column-by-column to obtain interleaved partial code bits. FIG. 11 is a block diagram illustrating such row-by-row writing and column-by-column reading to interleave partial code bits according to an embodiment. The horizontal arrows in FIG. 11 represent row-by-row writing and the vertical arrows represent column-by-column reading of partial code bits.

A number of rows RI, or number of columns CI, or both, that is a power of 2 may be preferred for mother code lengths that are a power of 2, but other block interleaver sizes are possible. In the example shown in FIG. 11, RI is a power of 2, such as 2, 4, 8, 16, . . . .

With the partial code bits denoted c₁[1], c₁[2], . . . c, [W], where W is the size of the partial block to which interleaving is to be applied, the interleaved partial code bits c_{π}[1], c_{π}[2], . . . c_{π}[W] may be generated according to the following example pseudocode:

```
For j=1 to W/RI
  For i=1 to RI
    c_{π1}[i+(j−1)*RI] = c_{π1}[j+(i−1)*(W/RI)]
  End for
End for
```

Each row and/or column may also or instead be permuted (or written/read in different orders). A permutation sequence for row and/or column permutation, in combination with block interleaving, can be generated or otherwise obtained according to, for example, a bit-reversal order or a pseudo-random order. The pseudo-random order may be specified, for example, by a polynomial, by a table, or by a transform such as a Fourier transform, a Hadamard transform, a discrete cosine transform, or a wavelet transform.

Bit-reversed interleaving may be implemented with block interleaving as described above, but may instead be implemented without block interleaving in some embodiments.

Suppose that W partial code bits are to be interleaved and bit indices of those code bits in a mother polar code are denoted by i₁, i₂ . . . i_{W}. Without loss of generality, further suppose that i₁, i₂ . . . i_{W} are in ascending order. This is just an example, and partial code bits to be interleaved need not be consecutive.

In an embodiment, bit-reversed interleaving may involve writing the partial code bits into an interleaver, with bit indices i₁, i₂ . . . i_{W} in ascending order. The numbers 0, 1 . . . . W-1 are associated to the partial code bits with indices i₁, i₂ . . . i_{W}, respectively. Bit-reversed values of 0, 1 . . . . W-1 are then calculated or otherwise determined, as BitRev(0), BitRev(1) . . . . BitRev(W-1). Interleaved partial code bits are then read out from the bit indices associated to the numbers BitRev(0), BitRev(1) . . . . BitRev(W-1), in that order.

The bit-reversed value of an integer x is obtained as follows. First, the integer x is converted into binary expansion form [b₀, b₁ . . . bₙ]. Then the binary expansion is reversed to [bₙ . . . b₁, b₀], and is converted into an integer y. Bit-reversal in this example may be denoted [symbol] =BitRev(x).

Embodiments are not in any way restricted to these specific types of interleavers or interleaving, or even to one single type of interleaving. For example, different types of interleavers or interleaving may be applied to different subsets of a codeword, in an approach that may be referred to as hybrid interleaving or using a hybrid interleaver. Partial code bits that are to be interleaved may be further partitioned or divided into multiple subsets of code bits. The subsets may be separately interleaved, such as by using block interleaver(s) or interleaving for one or more subsets, and also using bit-reversed interleaver(s) or interleaving for one or more other subsets. The interleaved subsets are then concatenated together to obtain a hybrid interleaved block. Hybrid interleaving is not necessarily restricted to subdivided partial code bits, and may also or instead be applied to different subsets such as c₂ and c₁ in FIG. 10.

Thus, interleaving of a subset of encoded bits may involve block interleaving, bit-reversed interleaving, or another type of interleaving. Where there are multiple subsets of encoded bits to be interleaved, each subset may be interleaved separately, and the separate interleaving may involve the same or different types of interleaving for different subsets.

Another aspect of the present disclosure relates to what is referred to herein primarily as information bit recycling. Reducing a number of code bits to be transmitted, by performing rate matching such as puncturing or shortening for example, will lead to reduction of polarized subchannel capacity. For example, puncturing P encoded bits will lead to P subchannels degrading to zero or near-zero capacity. See L. Zhang, Z. Zhang, X. Wang, Q. Yu and Y. Chen, “On the puncturing patterns for punctured polar codes,” 2014 IEEE International Symposium on Information Theory, 2014, pp. 121-125, doi: 10.1109/ISIT.2014.6874807. If these degraded subchannels were selected as information subchannels, then their zero or near-zero capacity will cause catastrophic performance loss, which is unacceptable.

It is therefore preferred not to place information bits on zero-capacity bit indices that correspond to zero-capacity subchannels. Instead, according to some embodiments disclosed herein, these zero-capacity bit indices are flagged as frozen bit indices. However, this increases the number of frozen bit indices, and means that any information bits that were to be placed on these bit indices, for transmission over the corresponding subchannels for example, are in effect discarded because the frozen bit indices are set to a frozen bit value. To address this issue, in some embodiments the same number of bit indices with non-zero capacity are additionally flagged as information bit indices, and the information bits that would have been discarded on the flagged frozen bit indices are instead placed on the additionally flagged information bit indices. As a result, input bit values are placed on different bit indices instead of being placed on bit indices that are impacted by reducing the number of encoded bits. Unless otherwise specifically stated, references herein to zero-capacity channels or indices should be understood to include near-zero capacity channels, very low capacity channels, or other practical or functional equivalents.

This approach is generally referred to herein as information bit recycling. Information bits that would otherwise in effect be discarded because they are mapped to bit positions that degrade to zero (or very low) capacity because of a reduction in the number of encoded bits, for rate matching for example, are instead placed on different bit indices with higher capacity. In this sense, the information bits or the original degraded information bit indices may be considered to be recycled. In another sense, this approach may be considered a form of information bit replenishing, in that information bits or information bit indices that would otherwise be lost or discarded as a result of reducing the number of encoded bits are replenished by the additionally flagged information bit indices.

The following notation may be useful in further describing embodiments related to information bit recycling:

Q=[Q₁, Q₂ . . . Q_{N}] is a reliability sequence, in ascending reliability order, where Qᵢ is the bit index of a bit position having an i-th lowest reliability in the reliability sequence.

The information set in a mother code (without any puncturing or shortening) is denoted by I, and includes the last K (i.e., the K most reliable) bit indices in Q, such that I={Q_{N-K+1}, Q_{N-K+2} . . . Q_{N}}.

The punctured set (for embodiments that include puncturing) is the set of punctured bit indices, denoted herein by P, and is determined based on a specific puncturing pattern that is to be applied for rate matching. Puncturing may be partially interleaved puncturing as disclosed herein, or fully interleaved puncturing, for example. Information bit recycling may be implemented in conjunction with interleaving but is not dependent upon interleaving. Information bit recycling also is not in any way dependent upon puncturing, and may apply more generally to reducing a number of encoded bits. Nevertheless, embodiments that include puncturing and/or interleaving may yet benefit from information bit recycling.

Information subchannels in I that still have non-zero capacity after puncturing are referred to herein as a “transmitted information set”, denoted by I_{T}. This notation is only for ease of reference, and is in the context of encoded bits being output for transmission. It should be noted, however, that embodiments are not restricted to transmission of encoded bits. Information bit recycling features and other featured that are disclosed herein with reference to transmission may apply more generally to other embodiments that may involve other forms of outputting encoded bits (such as outputting encoded bits to a storage medium) and need not necessarily involve transmission of the encoded bits.

Information bit indices corresponding to subchannels that degrade to zero capacity due to puncturing are referred to herein as a “punctured information set”, denoted by I_{P}.

$$I = {I}_{T} ⋃ {I}_{P} and Φ = {I}_{T} ⋂ {I}_{P} ,$$

where Φ is the empty set.

The newly added bit indices with non-zero capacity are referred to as a “replenished information set”, denoted by I_{R}.

Information bit recycling may involve determining I_{P} and I_{T}, determining I_{R}, and copying information bits, each of which is described in further detail by way of example herein, at least below.

Regarding I_{P} and I_{T}, given the P punctured bit indices, the bit indices corresponding to the resultant zero-capacity subchannels may be denoted I₀. The punctured information set I_{P} is the intersection between I and I₀, which may be expressed as I_{P}=I∩I₀. The transmitted information set is the complement set of I_{P} in I, which may be expressed as I_{T}=I\I_{P}={i:i∈I and i∉I_{P}}.

In most cases, it is expected that the bit indices corresponding to the zero-capacity subchannels I₀ will be the same as the bit indices in the punctured set P. In these cases, I_{P}=I∩P. In other words, it is expected that puncturing a bit from an i-th bit index in a codeword or encoded bits of a mother code, to reduce the number of encoded bits, results in the i-th bit index in an input vector being degraded to zero capacity.

The number of punctured information bits is denoted by |I_{P}|.

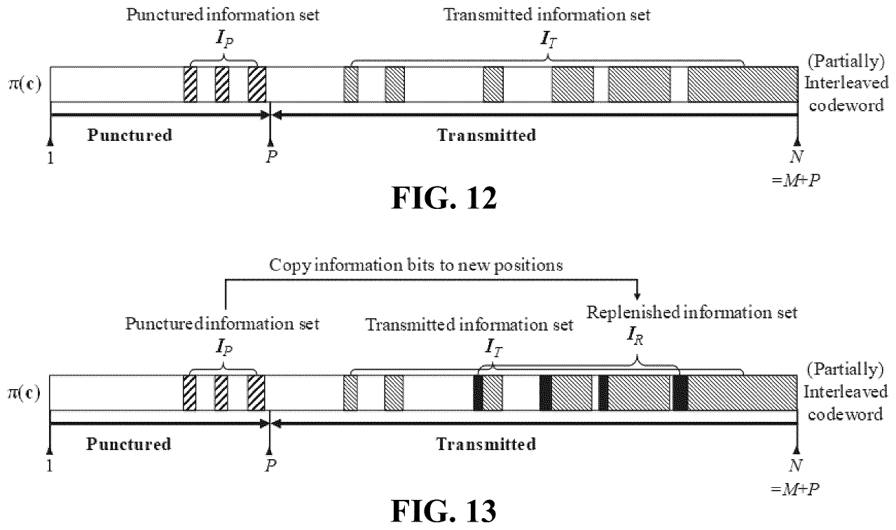

FIG. 12 is a block diagram illustrating punctured and transmitted information sets I_{P} and I_{T} in a partially interleaved codeword π(c). It should be noted, however, that a partially interleaved codeword is shown as an example. Features related to determining I_{P} and I_{T}, and more generally features related to information bit recycling, are not in any way dependent upon partial interleaving or any other type of interleaving.

The replenished information set I_{R} may be identified or selected as the most reliable |I_{P}| frozen bit indices that have non-zero subchannel capacity. These |I_{P}| frozen bit indices are flagged or selected as, converted to, or otherwise re-designated as information bit indices for the |I_{P}| information bits that would otherwise be discarded.

In the case that I₀=P, the replenished information set I_{R} can be obtained in a manner consistent with the following example pseudocode.

```
I_{R} = Φ;
For i = Q_{N} to Q₁
  If i ∉ I and i ∉ P
    I_{R} = [I_{R}, i] (add i to I_{R});
  End if
  If |I_{R}| == |I_{P}|
  Break;
  End if
End if
```

Information bits that were previously placed on (or were to be placed on) bit indices in I_{P} are now placed on bit indices in I_{R}. How rate matching is to be done (by puncturing and/or shortening for example) may be known or determined in advance, based on configuration or target code length for example. Therefore, the subchannels (and equivalently the corresponding bit indices for encoding) that degrade to zero or very low capacity due to rate matching (and that should be avoided for carrying information bits) can be determined before encoding. Although an information set and frozen set can be initially determined based on a number of information bits to be encoded and a reliability sequence such as Q above, values of input bits that have been placed on bit indices corresponding to zero-capacity subchannels can be copied to, or otherwise placed on bit indices that were initially part of the frozen set. This may involve copying of those information bit values between bit indices, moving those information bit values between bit indices, or otherwise placing those information bit values on newly designated or flagged information bit indices if the information bit values had not previously been placed on the bit indices that degrade to zero capacity due to rate matching.

This can perhaps best be seen in FIG. 13, which is a block diagram illustrating information bit copying from a punctured information set to a transmitted information set according to an embodiment. In FIG. 13, information bits that have been placed on zero capacity bit indices due to rate matching, shown as I_{P} in FIG. 13, are copied to new bit indices in I_{R}. Bit copying is referenced in the example shown in FIG. 13, and may be how information bit recycling is implemented in many embodiments, but information bit recycling is not limited to embodiments that involve an explicit “copy” operation. Although copying is a feasible solution for placing information bit values onto additionally flagged or re-designated information bit indices, it should be appreciated that information bit values could instead be placed onto newly flagged or re-designated information bit indices without first placing information bit values onto the zero capacity bit indices. Generally, a placing or moving operation may be accomplished in other ways that do not involve bit index-to-index copying.

In general, if there are P punctured bit indices from which encoded bits are punctured or otherwise reduced, then there will be exactly P bit indices with zero capacity. Puncturing or otherwise reducing the first P encoded bits at the first P bit indices in a codeword of a polar code, for example, will most significantly degrade the first P bit indices in an input vector. Similarly, for many other puncturing or encoded bit reduction patterns, a zero-capacity (or near-zero capacity) bit index pattern is identical to the puncturing or encoded bit reduction pattern, such that bit indices in an encoding input vector that are impacted by encoded bit reduction are the same as bit indices from which encoded bits are punctured or otherwise reduced. There can be exceptions, when puncturing from the end of a codeword for example, and for such scenarios an impacted input vector bit index pattern or its relationship to a puncturing or encoded bit reduction pattern may be defined or specified in a communication standard for example.

There is a relationship between bit indices of encoded bits that are punctured or otherwise reduced in rate matching and bit indices for encoding, which are bit indices in an input vector that are most significantly impacted or affected by reducing the number of encoded bits. Correspondence between a number of reduced encoded bits and a number of encoding input vector bit positions, and correspondence between reduced encoded bit indices and encoding input vector bit indices, are examples of relatively simple deterministic relationships, but the present disclosure is not in any way restricted to such relationships.

The foregoing example of information bit recycling identifies information bits or information bit indices that will be affected by reducing the number of encoded bits. Information bit indices of a polar code that correspond to punctured or otherwise reduced encoded bits are recycled. Another embodiment involves recycling information bits more aggressively.

Suppose that, as in an earlier example, a mother codeword is divided or partitioned into subsets. These subsets may be separated into two categories, including punctured subset(s) and non-punctured subset(s). Specifically, if any encoded bit(s) in a subset is punctured or otherwise reduced, then that subset is a punctured subset. On the other hand, a non-punctured subset has no encoded bits punctured or otherwise reduced, and all of its encoded bits remain after the number of encoded bits have been reduced.

Aggressive information bit recycling may be described in terms of modified information sets I′_{P} and I′_{T}. All information bit indices in punctured subsets are included in the punctured information set I′_{P}. This is a more aggressive way than the previous example because some of the bit indices in I′_{P} may still have non-zero subchannel capacity, but their subchannel capacity is very low and transmitting information bits over these subchannels by placing the information bit values on corresponding bit indices may still lead to performance degradation. The transmitted information set in this example is I′_{T}=I\I′_{P}.

The replenished information set I′_{R} for aggressive information bit recycling may be determined as the most reliable |I′_{P}| frozen bit indices in the non-punctured subset(s).

Similar to the previous example of information bit recycling, the information bits that were previously placed on bit indices in the punctured information set, which is I′_{P} for aggressive information bit recycling, are now copied to, moved to, or otherwise placed on bit indices in I′_{R}.

Subset size for identifying punctured and non-punctured subsets may be calculated, determined, or otherwise obtained in any of various ways. For example, subset size for aggressive information bit recycling may be specified in a communication standard or specification. With shorter subset size, aggressive information bit recycling may approach the earlier example of information bit recycling, in that shorter subsets are less likely to include additional information bits in addition to information bits associated with the punctured information set I_{P} simply because the subsets are shorter. Longer subset size increases the likelihood that more information bits will be recycled. Aggressive information bit recycling may have better performance as a result of more information bits being placed on bit indices with higher capacity, but this comes at a cost of higher complexity for subset partitioning and punctured/non-punctured subset identification, and having to copy, move, or otherwise place more information bit values on different bit indices.

A simple and unified description method can be important for describing a code ensemble that may include thousands of (N, K) codes. In communication standards or specifications, for example, such description efficiency may be a primary concern.

Another aspect of the present disclosure relates to parameterized configuration and/or parameter-based description, which may be particularly convenient and efficient for fine-grained partial interleaving. Fine-grained partial interleaving as disclosed herein involves separately interleaved subsets of a codeword, potentially using different types of interleavers and interleaving.

For example, for parameterized configuration and/or parameter-based description of fine-grained interleaving, two parameter vectors may be sufficient to describe a wide range of partial interleaving patterns.

A subset size vector [W₁, W₂, W₃ . . . ], where each element specifies the size W of a subset to be separately interleaved, may be used to configure and/or describe subset size for separate interleaving. Subset size may be indicated or represented in any of various ways, as an absolute number of encoded bits per subset or as a relative number or measure for example. A relative number with respect to mother code length N, for example, may indicate subset size as a portion of mother code length, such as 1/4 to indicate that subset size is N/4. An equivalent relative measure is the number of equal-size subset per mother codeword, in which case a value of 4, for example, also indicates a subset size of N/4.

An interleaver type or interleaving type vector [RI₁, RI₂, RI₃ . . . ], wherein each element specifies the number of rows RI of a block interleaver may also be employed in some embodiments. Special cases may be indicated by particular values of RI. For example, two special cases may be as follows: RI=1, or another special value or symbol, to indicate no interleaver or interleaving is to be applied (because a block interleaver with only one row is equivalent to not interleaving); and RI=0, or another special value or symbol, to indicate a bit-reversed interleaver or interleaving is to be applied. In the case of block interleaving, the number of columns of a block interleaver for a subset can be determined from the subset size and the number of interleaver rows.

Table 1 below provides an example of a two-vector parameter-based configuration or description format for fine-grained partial interleaving.

TABLE 1
Example Two-Vector Partial Interleaving Parameter Table

| Subset size | W₁ | W₂ | W₃ | . . . |
|---|---|---|---|---|
| Interleaver type | RI₁ | RI₂ | RI₃ | . . . |

Table 2 below is populated with parameter values for an example in which a codeword is to be divided into three subsets, with lengths N/4, N/4 and N/2, respectively, and the first subset is to be interleaved by a block interleaver with 2 rows and (N/4)/2=N/8 columns, the second subset is to be interleaved by another block interleaver with 4 rows and (N/4)/4=N/16 columns, and the third subset is not to be interleaved.

TABLE 2
Example Parameters for Three-Subset Partial Interleaving

| ¼ | ¼ | ½ |
|---|---|---|
| 2 | 4 | 1 |

Table 3 below is populated with parameter values for an example in which a codeword is to be divided into four subsets, with lengths N/8, N/8, N/4 and N/2, respectively, and the first subset is not to be interleaved, the second subset is to be interleaved by a block interleaver with 8 rows, the third subset is to be interleaved by another bit-reversed interleaver, and the fourth subset is not to be interleaved.

TABLE 3
Example Parameters for Four-Subset Partial Interleaving

| ⅛ | ⅛ | ¼ | ½ |
|---|---|---|---|
| 1 | 8 | 0 | 1 |

Tables 1 to 3 are examples only. The present disclosure is not in any way limited to these particular examples.

Various features are described above, and further detailed illustrative examples are provided below. The detailed examples are for information bit recycling, with and without partial interleaving, and demonstrate that information bit recycling may be implemented independently from or in conjunction with partial interleaving. Similarly, partial interleaving may be implemented independently from or in conjunction with information bit recycling. Information bit recycling and partial interleaving have their own respective benefits, which are not in any way dependent upon each other.

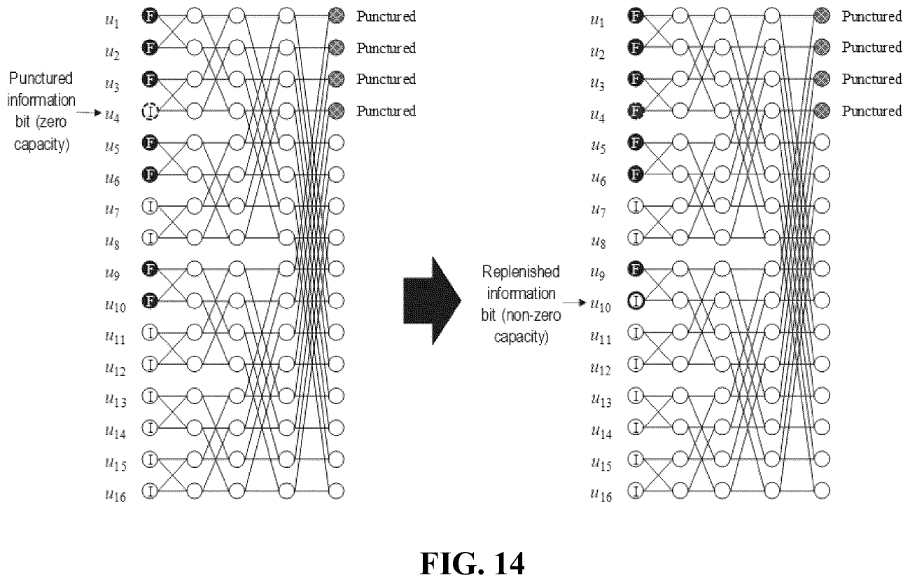

FIG. 14 includes trellis graphs illustrating information bit recycling according to an example (M=12, K=9) polar code, with an information set under mother code length N=16 of I={4, 7, 8, 11, 12, 13, 14, 15, 16} and a frozen set F={1, 2, 3, 5, 6, 9, 10}, with sequential puncturing applied to a non-interleaved codeword. The punctured set is P={1, 2, 3, 4}.

In this code construction with puncturing, the fourth input bit u₄ to polar coding corresponds to a punctured encoded bit in the punctured set, and in this sense may be considered and referred to as a punctured information bit or punctured information bit index, which has zero capacity. Placing an information bit value on this bit index will lead to catastrophic performance loss. Therefore, the fourth bit u₄ may be flagged as a frozen bit, and/or the bit index 4 may be flagged as a frozen bit index.

For information bit recycling, the most reliable frozen bit index that has non-zero capacity is identified. This is the 10-th bit u₁₀. Accordingly, the 10-th bit u₁₀, previously a frozen bit, may be flagged as an information bit and may be referred to as, for example, a replenished information bit. Equivalently, the index 10 may be flagged as an information bit index and may be referred to as, for example, a replenished information bit index.

During encoding, the input or source bit that was originally to be placed on bit index 4 is now placed on bit index 10. A frozen bit value, such as 0, is now placed on bit index 4.

The following examples involve both information bit recycling and partial interleaving.

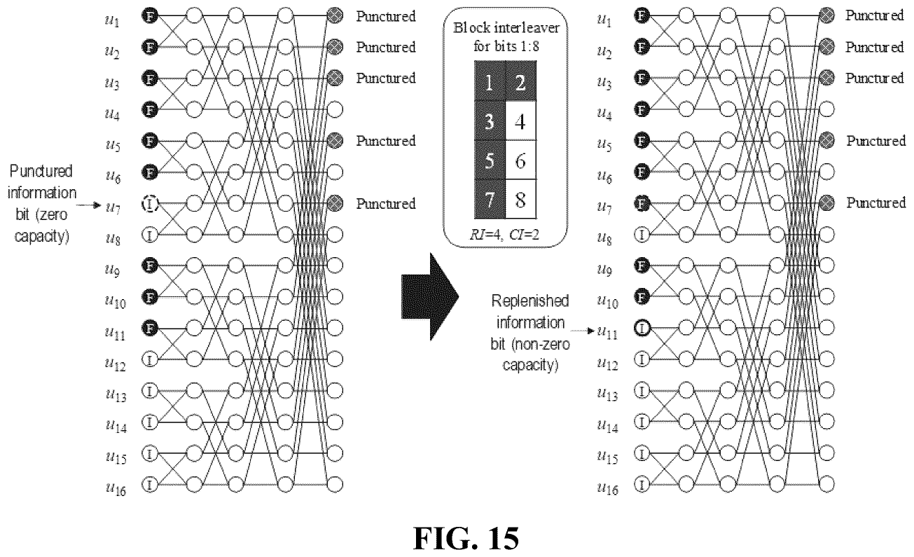

FIG. 15 includes trellis graphs illustrating information bit recycling and partial interleaving according to an example (M=11, K=7) polar code, with an information set under mother code length N=16 of I={7, 8, 12, 13, 14, 15, 16}, and a frozen set F={1, 2, 3, 4, 5, 6, 9, 10, 11}. Partially-interleaved puncturing is applied using the parameters in Table 4 below.

TABLE 4
Partial Interleaving Parameters for Illustrative Example

| ½ | ½ |
|---|---|
| 4 | 1 |

In the puncturing scheme of this example (N=16, M=11, K=7) polar code, the punctured set is P={1, 2, 3, 5, 7}. Block interleaving in this example is applied to the first subset of size N. W₁=N/2=8, and with the number of block interleaver rows RI₁=4, the number of block interleaver columns CI₁=W₁/RI₁=2. As a result of the block interleaver, which is shown in the middle of FIG. 15, the bits read-out in column-wise fashion will correspond to the set of bit indices {1, 3, 5, 7, 2, 4, 6, 8}. A downstream rate-matching operation may conveniently puncture the first five (N-M) bit positions of the partially interleaved codeword to carry out the puncturing scheme of this example code.

With this code construction, the 7-th bit u₇ is a punctured information bit, and bit index 7 has zero capacity. Placing an information bit value on this bit index will lead to catastrophic performance loss. Therefore, the 7-th bit u₇, which was initially defined or identified as an information bit, will be redefined as a frozen bit. In other words, bit index 7, which was initially defined or identified as an information bit index in the information set, will be redefined as a frozen bit index in the frozen set.

The most reliable frozen bit index that has non-zero capacity is identified, and in this example is the bit index 11 of the 11-th bit u₁₁. Accordingly, the 11-th bit u₁₁ is flagged as a replenished information bit, or in other words bit index 11 becomes an information bit index in I_{R}.

During encoding, the input or source bit value that was to be placed on bit index 7 is now placed on bit index 11. A frozen bit value, such as 0, is instead placed on bit index 7. The result of these operations is shown on the right-hand side of FIG. 15.

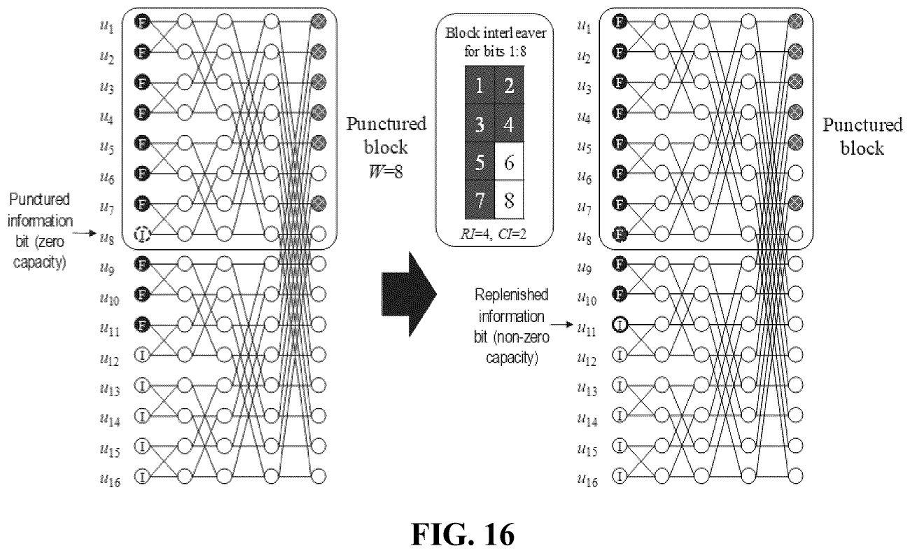

A third example involves more aggressive information bit recycling and partial interleaving. FIG. 16 is a block diagram that includes trellis graphs illustrating such an embodiment.

FIG. 16 is consistent with an (M=10, K=6) polar code, for which the information set under mother code length N=16 is I={8, 12, 13, 14, 15, 16} and the frozen set is F={1, 2, 3, 4, 5, 6, 7, 9, 10, 11}. Partially-interleaved puncturing is applied using the same parameters in Table 4 above. In the puncturing scheme of this example polar code, the punctured set is P={1, 2, 3, 4, 5, 7}. As illustrated in the block interleaver shown in the middle of FIG. 16, the bits read-out in column-wise fashion will correspond to the set of bit indices {1, 3, 5, 7, 2, 4, 6, 8}. A downstream rate-matching operation may conveniently puncture the first six (N-M) bit positions of the partially interleaved codeword to carry out the puncturing scheme of this example code.

In this example, the 8-th bit u₈ is not a punctured information bit, and has non-zero capacity. However, with block size N/2=8, it belongs to the punctured subset (bits 1:8), and thus the 8-th bit index of us has very low capacity. Placing an information bit value on this bit index may lead to significant performance loss. Therefore, with more aggressive information bit recycling, the 8-th bit us is flagged as a frozen bit, and the bit index 8 becomes a frozen bit index.

The most reliable frozen bit index in the non-punctured subset (bits 9:16) is identified as the 11-th bit index of the bit u₁₁ in this example. Accordingly, the 11-th bit u₁₁ may be flagged as a replenished information bit, and the bit index 11 becomes an information bit index in I_{R}.

During encoding, the input or source bit value that was to be placed on bit index 8 is now instead placed on bit index 11, and a frozen bit value, such as 0, is placed on bit index 8. The result of these operations is shown on the right-hand side of FIG. 16.

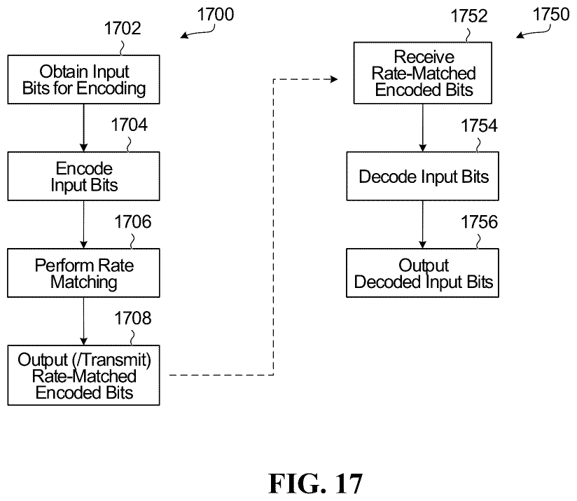

Various aspects of the present disclosure are described above and shown in the drawings by way of example. FIG. 17 is a flow diagram illustrating more general example methods according to embodiments. At the left, 1700 in FIG. 17 illustrates operations or features that may be provided or supported at an encoder or transmitter-side device, and at the right, 1750 illustrates operations or features that may be provided or supported at a decoder or receiver-side device. For ease of reference, in the following description of FIG. 17, a device at which encoding and/or transmitting features may be implemented or supported is called a first communication device, and a device at which decoding and/or receiving features may be implemented or supported is called a second communication device. Embodiments may involve either or both of such devices.

With reference first to 1700, from a transmitting device perspective the outputting of encoded bits may involve transmitting the encoded bits at 1708. Encoded bits may be output through or via any of various types of interface, including a communication interface in the case of transmitting the encoded bits. Embodiments are not in any way restricted to any particular type of interface. The encoded bits may be transmitted at 1708 by a first communication device to a second communication device in a wireless communication network, for example. The encoded bits are obtained by encoding input bits by a polar code at 1704, and may be referred to as encoded bits encoded by the polar code. Encoding at 1704 may be implemented or performed by an encoder or a processor, for example. Encoding at 1704 may further include interleaving a subset of the encoded bits. The subset of bits for interleaving includes bits that are not intended for transmission, such as bits intended for puncturing.

A polar code comprises or provides bit indices for placing values of input bits before encoding. The bit indices include a first set of bit indices for placing values of the input bits, and a second set of bit indices for placing a predetermined bit value. Bit value placement on bit indices is not shown separately in FIG. 17, and may be considered to be part of the encoding at 1706.

Rate matching may be performed at 1706, by an encoder or a rate matching module for example, to reduce the number of encoded bits obtained by the encoding at 1704. This may involve, for example, puncturing and/or shortening. According to embodiments disclosed herein, the rate matching is performed to reduce a number of the encoded bits in an interleaved subset of the encoded bits. Examples provided above refer to blocks of a codeword, and partial interleaving of only some, but not all, of such blocks. It should therefore be understood that a block includes only some encoded bits that are obtained by encoding input bits. Subsets of encoded bits are referenced herein to perhaps more directly convey the property that a subset includes fewer than all of the encoded bits obtained by encoding at 1704. Features disclosed herein in the context of subsets of encoded bits, code bits, or codewords may also or instead apply to blocks, parts, or portions of encoded bits, code bits, or codewords.

The rate matching at 1706 is performed, at least in part, on an interleaved subset of encoded bits. In this way, the number of encoded bits in the subset is reduced, and accordingly the subset is for reducing the number of the encoded bits. As shown by way of example in FIG. 9, rate matching by puncturing in this example need not necessarily be performed only on an interleaved subset of encoded bits. The example in FIG. 9 illustrates puncturing of a non-interleaved subset c₀ and an interleaved subset π(c₁). A subset of encoded bits may be entirely punctured, as shown by way of example for c₀ in FIG. 9 and also for π(c₂) in FIG. 10, or partially punctured, as shown by way of example in FIG. 8 and also for at (c₁) in each of FIGS. 9 and 10. Performing rate matching, or more generally reducing the number of encoded bits, therefore involves reducing the number of encoded bits in a subset that includes fewer than all of the encoded bits, but may also involve reducing the number of encoded bits in other subsets as well.

Reducing the number of encoded bits need not change the number of encoded bits that are obtained by the encoding at 1704. Input bits are encoded to obtain encoded bits, and the number of encoded bits is subsequently reduced, by performing the rate matching at 1706 in the example shown in FIG. 17. The fact that the number of encoded bits, for transmission or output in some other way at 1708, is reduced does not change the number of encoded bits obtained by the encoding at 1704. For example, reduction in the number of encoded bits at 1706 does not reduce the number of encoded bits obtained for the codeword c in each of FIGS. 7 to 10.

Another operation that may be involved in obtaining encoded bits is illustrated at 1702. Obtaining input bits may involve, for example, collecting or otherwise receiving data outputs from one or more devices and/or services, or accessing data in a memory.

As shown at 1708, a method may also involve outputting the reduced number of encoded bits. The reduced number of encoded bits that remain after the reduction in the number of encoded bits at 1706 may be output for storage to memory, and/or transmission, for example.

Embodiments may include any or all of the operations illustrated at 1700. For example, in some embodiments, a method may involve encoding as shown at 1704 and transmitting or otherwise outputting the reduced number of encoded bits at 1708. Other embodiments may involve transmitting or otherwise outputting, at 1708, a reduced number of encoded bits that have already been obtained by encoding input bits by a polar code. Such embodiments are not mutually exclusive, and methods may involve the obtaining, encoding, and rate matching at 1702, 1704, 1706, and also outputting encoded bits as shown at 1708.

Other features may also or instead be provided or supported.

For example, the encoded bits encoded by the polar code at 1704 may be in an order, and the subset may include encoded bits that are non-consecutive in that order. An example is shown in FIG. 8, in which non-consecutive encoded bits in the codeword c are aggregated into a subset and interleaved before puncturing.

In another embodiment, the encoded bits encoded by the polar code at 1704 may again be in an order, but the subset for interleaving is preceded by and followed by other encoded bits in the order. See FIG. 9, for example, in which the second subset c, is interleaved, and is preceded by and followed by other encoded bits. This may also be referred to as the encoded bits that are to be interleaved being positioned or “sandwiched” between other encoded bits.

Some embodiments may involve multiple interleavers, or more generally multiple interleaved subsets of encoded bits. For example, the subset referenced above may be one of a plurality of subsets of the encoded bits obtained by encoding the input bits. Each subset includes a unique subset of fewer than all of the encoded bits, so that there is no overlap between the subsets, or in other words there are no common encoded bits in multiple subsets. The encoded bits in all of the to-be-interleaved subsets include fewer than all of the encoded bits. There may be other subsets of encoded bits that are not to be interleaved, but according to embodiments herein there is partial interleaving of encoded bits, meaning that a combination of all of the encoded bits in the subset(s) for interleaving does not include all of the encoded bits. FIG. 10, for example, illustrates multiple subsets c₁ and c₂ to be interleaved, but those subsets together do not include all of the encoded bits in the codeword c.

With multiple subsets for interleaving, the interleaving may involve separately interleaving the encoded bits in each subset. Performing rate matching, at 1706 for example, may then include performing the rate matching on the encoded bits to reduce a number of the encoded bits in each of the subsets. The number of encoded bits that are reduced from each subset may be the same or different, and FIG. 10 illustrates an example in which the number of encoded bits reduced from each subset is different.

Any of various different types of interleaving may be used to change the order of encoded bits within a subset. Examples are provided elsewhere herein, and include block interleaving and bit-reversed interleaving, any one of which may be used in interleaving a subset.

In embodiments that involve multiple subsets to be interleaved, the interleaving may involve the same or different types of interleaving for different subsets.

Embodiments referred to herein as information bit recycling may be implemented in conjunction with embodiments that also involve partial interleaving. For example, the first set of bit indices referenced above (for placing values of the input bits) may include a first bit index on which a value of an input bit is placed instead of the value of the input bit being placed on a second bit index that is impacted by reducing the number of the encoded bits in the subset. This is perhaps best illustrated in FIGS. 12 and 13. In this context and referring to the example above, a first bit index is a bit index in the replenished information set I_{R} and a second bit index is a bit index in the punctured information set I_{P}. An input bit value is placed on a first bit index in I_{R} instead of being placed on a second bit index in I_{P}.

This type of re-allocation or re-placement of a bit value on a different bit index could be considered a form of moving an input bit to the first bit index from the second bit index, copying an input bit to the first bit index from the second bit index, or redirecting an input bit to the first bit index from the second bit index, for example.

From a bit index perspective, information bit recycling may be considered a form of moving the first bit index from the second set of bit indices (the frozen set) to the first set of bit indices (the information set) for placement of the input bit value, or re-marking or re-designating the first bit index as an information bit index instead of a frozen bit index, for example. Similarly, from the perspective of the second bit index in the punctured information set, information bit recycling may be considered a form of moving the second bit index from the first set of bit indices (the information set) to the second set of bit indices (the frozen set), or re-marking or re-designating the second bit index as a frozen bit index instead of an information bit index.

Another way to interpret or express information bit recycling as disclosed herein is that encoding involves placing a value of an input bit on a bit index in the first set of bit indices (the information set, for placing values of the input bits) instead of on a second bit index that is impacted by reducing the number of the encoded bits in the subset.

In the example above, the first bit index is described in terms of the first set of bit indices (the information set, for placing values of the input bits) including the first bit index. Replenished bit indices like the first bit index in this example may be considered to be part of an information set or the above-referenced first set of bit indices for placing values of the input bits. In another embodiment, replenished bit indices may be considered to be part of a different set of bit indices, such as the replenished information set I_{R} referenced herein. Thus, the bit indices of a polar code may further comprise a third set of bit indices comprising a first bit index on which a value of an input bit is placed instead of the value of the input bit being placed on a second bit index that is impacted by reducing the number of the encoded bits in the subset.

In a communication standard or specification, for example, I_{R} could be defined as a subset of I_{T} or it may be defined separately as a different set of bit indices. The former is an example of the first set of bit indices of a polar code comprising the first bit index, and the latter is an example of the bit indices of a polar code further comprising a third set of bit indices comprising the first bit index.

More generally, the bit indices of a polar code may include one or more bit indices described by way of example herein as the first bit index, and one or more bit indices described by way of example herein as the second bit index.

Information bit recycling may involve recycling only information bits or bit indices that have zero capacity as a result of reducing the number of encoded bits. In other words, the second bit index referenced in the above example may correspond to a bit index of an encoded bit that is reduced from the subset.

In embodiments that are also referenced herein as more aggressive information bit recycling, one or more information bits or bit indices that do not directly correspond to a punctured or otherwise reduced encoded bit, but correspond to an encoded bit that is within the same subset or block as a reduced encoded bit, are also recycled. This may be considered a form of subset-based or subset-level information bit recycling, in that a recycling determination as to whether or not information bits or bit indices are to be recycled is made on a subset or block level rather than on an individual bit or bit index level. FIG. 16 illustrates an example, in which Us is recycled but its direct corresponding encoded bit cs is not punctured.

Using previous examples to further illustrate this type of information bit recycling, the second bit index may correspond to a bit index of an encoded bit that is reduced from the subset, and the first set of bit indices (or the third set of bit indices, or more generally the bit indices of the polar code) may further comprise a third bit index on which a value of a further input bit is placed instead of the value of the further input bit being placed on a fourth bit index that corresponds to an index of one of the reduced number of the encoded bits in the subset. In the example of FIG. 16, the third bit index for placing the input bit value is index 11 in the right-hand trellis, the fourth bit index on which the input bit value is not to be placed is index 8 in the left-hand trellis, and 8 is also the index of one of the reduced number of the encoded bits in the subset. The encoded bit c₈ is the one of the reduced number of the encoded bits in this example, in that c₈ remains in the subset after the number of encoded bits in the subset has been reduced.

Other embodiments may involve additional, fewer, and/or different features. For example, information bit recycling may be implemented in conjunction with partial interleaving, or separately.

A method related to information bit recycling may involve encoding input bits by a polar code to obtain a number of encoded bits and outputting a reduced number of the encoded bits, as described in detail elsewhere herein and shown by way of example at 1704, 1708 in FIG. 17. The polar code, as in other embodiments, comprises bit indices for placing values of the input bits before encoding, and the bit indices include a first set of bit indices for the values of the input bits and a second set of bit indices for a predetermined bit value. The encoded bits include a subset that includes fewer than all of the encoded bits and is for reducing the number of the encoded bits.

The bit indices include a respective first bit index on which a value of a respective input bit is placed instead of the value of the respective input bit being placed on a respective second bit index that corresponds to a bit index of each encoded bit in the subset. There may be one or more respective first bit indices (three of which shown by way of example as the replenished information set in FIG. 13) on which a value of a respective input bit is placed instead of being placed on a respective second bit index (three of which are shown by way of example as the punctured information set in FIG. 13), that corresponds to a bit index of each encoded bit in the subset. The one or more respective first bit indices and the respective second bit index that corresponding to a bit index of each encoded bit in the subset is intended to convey what is referred to herein as aggressive information bit recycling, in which each information bit in a subset that includes a punctured (reduced) information bit in the punctured (reduced) information set is recycled, regardless of whether its corresponding encoded bit is punctured or otherwise reduced from the subset of encoded bits.

Features disclosed herein may also or instead be embodied in other forms. An ordered sequence of polar code bit indices, for example, may embody, or be modified to embody, features related to partial interleaving and/or information bit recycling as disclosed herein.

A method, for example, may involve obtaining an ordered sequence indicating a plurality of bit indices for a polar code in an order of rank (by reliability for example) for placing values of input bits for encoding by the polar code to obtain a number of encoded bits. The bit indices include: a first set of bit indices of highest rank according to the ordered sequence, for placing the values of the input bits before encoding; and a second set of bit indices of lower rank than the highest rank according to the ordered sequence, for placing a predetermined bit value. Such a method may also involve encoding the input bits by the polar code according to the ordered sequence, to obtain the number of encoded bits at 1704 for example; and outputting the reduced number of the encoded bits at 1708 for example. Other features disclosed herein may also or instead be provided or supported in such a method.

The order of rank indicated by the ordered sequence is for reducing the number of the encoded bits. Thus, the order of rank is determined based on how encoded bit reduction impacts bit index rank for preference in placing values of the input bits. Depending on which encoded bits are punctured or otherwise reduced, some bit indices may become less reliable or otherwise of lower rank, and other bit indices may become more reliable or otherwise of higher rank. Rank may take into account either or both of information bit recycling and interleaving, to enable various features as disclosed herein to be implemented or supported by using an ordered sequence.

Obtaining an ordered sequence may involve selecting from a number of available ordered sequences. For example, ordered sequences for different mother code lengths, transmitted code lengths, puncturing patterns, etc., may be pre-generated and specified in a communication standard or specification, and then selected for use in encoding based on encoding parameters or conditions. Another possible option for obtaining an ordered sequence involves modifying a base sequence that indicates the bit indices for the polar code in a base order of rank for placing the values of input bits for encoding by the polar code to obtain the number of encoded bits, and the base order of rank is for outputting the number of the encoded bits. In other words, a base sequence that does not take encoded bit reduction, information bit recycling, or interleaving into account may be modified to obtain a sequence in which order of rank of bit indices is for reducing the number of the encoded bits. A communication standard or specification may specify one or more base sequences, and possibly instructions for modifying the base sequence(s) according to encoding parameters or conditions. The above-referenced reliability sequence Q=[Q₁, Q₂ . . . Q_{N}], indicating bit indices in ascending reliability order, is an example of a base sequence.

At 1750, FIG. 17 illustrates various decoding and/or receiving counterparts of features shown at 1700. From a receiving device perspective, the receiving at 1752 represents receiving a reduced number of encoded bits that have been encoded by a polar code. The receiving at 1752 may involve receiving the encoded bits from a first communication device by a second communication device in a wireless communication network, for example. Encoded bits may be received through or via any of various types of interface, and embodiments are not in any way restricted to any particular type of interface.

The polar code, as in other embodiments herein, comprises bit indices for placing values of input bits, and the bit indices comprise a first set of bit indices for the values of the input bits, and a second set of bit indices for a predetermined bit value. The received reduced number of encoded bits include encoded bits that remain after reduction in a number of the encoded bits in an interleaved subset of fewer than all of the encoded bits.

The decoding at 1754 is intended to illustrate decoding the received reduced number of encoded bits to obtain decoded input bits. Decoding at 1754 may be implemented or performed by a decoder or a processor, for example.

In some embodiments, a decoder might not be a discrete device, but rather a block of logic in silicon or part of a system-on-chip that decodes and uses the decoded input bits. In other embodiments, the decoded input bits are output as shown at 1756, for processing and/or storage, for example.

Any or all of the features that are described herein in the context of encoder-side or transmitter-side methods, with reference to operations at 1700 in FIG. 17, for example, may also apply to or have counterpart features in a decoder-side or receiver-side method. Any one or more of the following features, for example, may be provided or supported, individually or in any of various combinations, in a decoder-side or receiver-side method:
the encoded bits encoded by the polar code are in an order;
the subset comprises encoded bits that are non-consecutive in the order;
the subset is preceded by and followed by other encoded bits in the order;
the reduction in the number of the encoded bits in the interleaved subset involves rate matching;
the subset comprises one of a plurality of subsets of the encoded bits;
each subset comprises a unique subset of fewer than all of the encoded bits and the plurality of subsets together comprise fewer than all of the encoded bits;
the encoded bits in each subset of the plurality of subsets of the encoded bits are separately interleaved prior to reduction in a number of the encoded bits in each of the subsets;
the encoded bits in each subset of the plurality of subsets of the encoded bits are separately interleaved prior to the rate matching for reduction in a number of the encoded bits in each of the subsets;
the subset is interleaved by any one of: block interleaving and bit-reversed interleaving;
where there are multiple subsets, each subset is interleaved by any one of: block interleaving and bit-reversed interleaving;
the encoded bits in different subsets are separately interleaved by different types of interleaving;
the first set of bit indices comprises, or more generally the bit indices comprise, a first bit index on which a value of an input bit was placed instead of the value of the input bit being placed on a second bit index that is impacted by the reduction in the number of the encoded bits;
the bit indices further comprise a third set of bit indices comprising a first bit index on which a value of an input bit was placed instead of the value of the input bit being placed on a second bit index that is impacted by the reduction in the number of the encoded bits;
the second bit index corresponds to a bit index of an encoded bit that was reduced from the subset;
the first set of bit indices further comprises, or more generally the bit indices further comprise, a third bit index on which a value of a further input bit was placed instead of the value of the further input bit being placed on a fourth bit index that corresponds to an index of one of the reduced number of the encoded bits in the subset;
the third set of bit indices further comprises a third bit index on which a value of a further input bit was placed instead of the value of the further input bit being placed on a fourth bit index that corresponds to an index of one of the reduced number of the encoded bits in the subset.

Information bit recycling may be implemented or supported in conjunction with or independently from partial interleaving. For example, in an independent embodiment a method may involve receiving, at 1752, a reduced number of encoded bits encoded by a polar code. The polar code comprises a plurality of bit indices for placing values of input bits, and the bit indices comprise a first set of bit indices for the values of the input bits, and a second set of bit indices for a predetermined bit value. The received reduced number of encoded bits comprise encoded bits that remain after reduction in a number of the encoded bits in a subset of the encoded bits that includes fewer than all of the encoded bits. The bit indices comprise a respective first bit index on which a value of a respective input bit was placed instead of the value of the respective input bit being placed on a respective second bit index that corresponds to a bit index of each encoded bit in the subset. Such a method may also involve decoding the reduced number of encoded bits at 1754 to obtain decoded input bits.

A sequence-based approach, described in an example above from an encoding perspective, may have counterpart receiving, decoding, and other features. A method may involve receiving a reduced number of encoded bits encoded by a polar code, with the polar code comprising a plurality of bit indices for placing values of input bits for encoding to obtain a number of encoded bits, and the bit indices comprising: a first set of bit indices of highest rank according to an ordered sequence, for placing values of the input bits before encoding; and a second set of bit indices of lower rank than the highest rank according to the ordered sequence, for placing a predetermined bit value. The ordered sequence indicates the plurality of bit indices in an order of rank for placing the values of the input bits, and the order of rank is for reducing the number of the encoded bits to the reduced number of the encoded bits. Such a method may also involve decoding the reduced number of encoded bits to obtain decoded input bits. A sequence-based method of this type is also consistent with a method shown in FIG. 17, including receiving at 1752 and decoding at 1754.

The ordered sequence in this example may have been obtained by selecting from among available sequences, or may have been obtained by modifying a base sequence. The base sequence may indicate the plurality of bit indices for the polar code in a base order of rank for placing the values of input bits for encoding by the polar code to obtain the number of encoded bits, with the base order of rank being for outputting the number of the encoded bits rather than the reduced number of the encoded bits.

Embodiments may involve other features or operations as well. For example, some embodiments may involve communicating signaling that is indicative of any of various parameters, such as any one or more of: MCS index, code length, code rate, puncturing pattern, base sequence, etc. Communicating of signaling may involve transmitting the signaling by an encoder/encoding device or a transmitter/transmitting device that is to transmit encoded bits, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which encoded bits are to be transmitted or received. For example, a network device such as a gNB or a base station may transmit signaling to configure parameters at one or more communication devices. Therefore, a method may involve a network device transmitting signaling, and an encoder/encoding device or a transmitter/transmitting device receiving the signaling from the network device, and/or a decoder/decoding device or a receiver/receiving device receiving the signaling from the network device.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor that is configured, by executing programming for example, to cause the apparatus to perform a method or operations, or to provide or support features, disclosed herein. An apparatus may also include a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to encode input bits by a polar code to obtain a number of encoded bits, with the polar code comprising a plurality of bit indices for placing values of the input bits before encoding, and the bit indices comprising a first set of bit indices for the values of the input bits, and a second set of bit indices for a predetermined bit value. Programming may also include instructions to or to cause a processor to interleave a subset of the encoded bits. The subset includes fewer than all of the encoded bits, and is for reducing the number of the encoded bits. In some embodiments, programming may also include instructions to or to cause a processor to outputting the reduced number of the encoded bits.

Other embodiments may similarly be implemented using programming that includes instructions to or to cause a processor to encode input bits by a polar code to obtain a number of encoded bits, and output a reduced number of the encoded bits. The polar code comprises a plurality of bit indices for placing values of the input bits before encoding, and the bit indices comprise a first set of bit indices for the values of the input bits, and a second set of bit indices for a predetermined bit value. The encoded bits comprise a subset including fewer than all of the encoded bits, and the subset is for reducing the number of the encoded bits. The bit indices comprise a respective first bit index on which a value of a respective input bit is placed instead of the value of the respective input bit being placed on a respective second bit index that corresponds to a bit index of each encoded bit in the subset. This is illustrative of a programming embodiment of information bit recycling as disclosed herein.

According to another programming embodiment, programming includes instructions to or to cause a processor to obtain an ordered sequence indicating a plurality of bit indices for a polar code in an order of rank for placing values of input bits for encoding by the polar code to obtain a number of encoded bits, encode the input bits by the polar code according to the ordered sequence to obtain the number of encoded bits, and output a reduced number of the encoded bits. The bit indices comprise: a first set of bit indices of highest rank according to the ordered sequence, for placing the values of the input bits before encoding; and a second set of bit indices of lower rank than the highest rank according to the ordered sequence, for placing a predetermined bit value, and the order of rank is for reducing the number of the encoded bits.

Apparatus embodiments are not limited to the foregoing examples of programming-based embodiments. An apparatus may also or instead include, for example: an encoder for encoding input bits by a polar code to obtain encoded bits; an interleaver coupled to the encoder, for interleaving a subset of the encoded bits; and an interface coupled to the encoder for outputting a reduced number of the encoded bits. As in other embodiments, the polar code comprises bit indices for placing values of the input bits before encoding, and the bit indices comprise a first set of bit indices for the values of the input bits, and a second set of bit indices for a predetermined bit value. The subset of the encoded bits for interleaving by the interleaver includes fewer than all of the encoded bits, and is for reducing the number of the encoded bits.

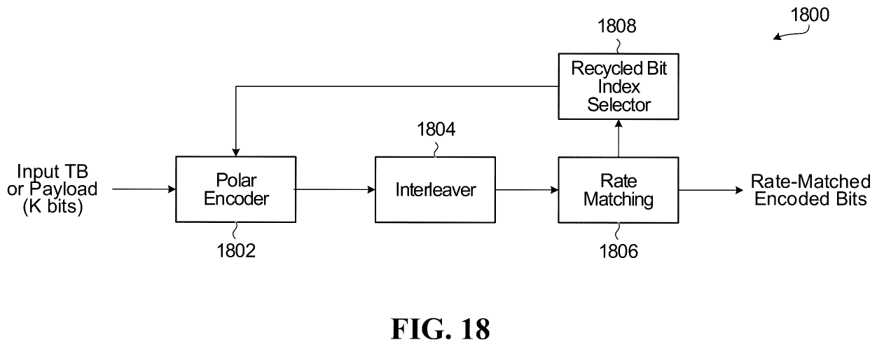

FIG. 18 is a block diagram illustrating an apparatus in which such an embodiment may be implemented or supported. The example apparatus 1800 includes a polar encoder 1802, an interleaver 1804 coupled to the polar encoder, a rate matching module 1806 coupled to the interleaver, and a recycled bit index selector 1808 coupled to the rate matching module and to the polar encoder. Input bits for encoding are shown as input TB or payload bits, and rate-matched encoded bits are shown as an output of the rate matching module 1806. An interface for transmitting or otherwise outputting the reduced number of encoded bits may be provided by, incorporated into, or coupled to, any one or more of the polar encoder 1802, the interleaver 1804, and the rate matching module 1806.

Encode-side or transmit-side features or functions, and other features or functions herein, may be implemented in any of various ways, such as in hardware, firmware, or one or more components that execute software. The present disclosure is not limited to any specific type of implementation, and implementation details may vary between different devices, for example.

In the example apparatus 1800, the polar encoder 1802 is configured, by executing software for example, to encode bits to obtain encoded bits. The interleaver 1804 is configured, by executing software for example, to interleave a subset of the encoded bits. Non-interleaved encoded bits may be output by the interleaver 1804 in an order in which they are provided by the polar encoder 1802, or may be provided by the polar encoder to the rate matching module 1806. Not all embodiments involve interleaving, and accordingly the interleaver 1804 is optional.

The rate matching module 1806 is configured, by executing software for example, to perform rate matching, and may include a circular buffer for storing encoded bits from the interleaver 1804, and/or possibly the polar encoder 1802 if non-interleaved encoded bits bypass the interleaver or no interleaving is to be performed or supported.

The recycled bit index selector 1808 is configured, by executing software for example, to implement or support information bit recycling, by selecting an alternative bit index on which an input bit value is to be placed for encoding by the polar encoder 1802, instead of another bit index that is impacted by rate matching. The recycled bit index selector 1808 is another optional component. For example, in sequence-based embodiments information bit recycling is in effect incorporated into an ordered sequence that is used by the polar encoder 1802, and the recycled bit index selector 1808 need not be provided.

The apparatus 1800 is intended purely as an illustrative example. Embodiments are not in any way limited to implementation in the manner shown. Apparatus embodiments may include fewer, additional, and/or different components.

More generally, an apparatus or a component thereof such as an encoder 1802 or a processor may be configured to, or programming may include instructions to or to cause a processor to: encode input bits to obtain a number of encoded bits. In some embodiments, an apparatus or a component thereof such as an interleaver 1804 or a processor may be configured to, or programming may include instructions to or to cause a processor to: interleave encoded bits in a subset of the encoded bits that includes fewer than all of the encoded bits and is for reducing the number of encoded bits.

Such an apparatus or a component thereof such as an interface may be configured to, or programming may include instructions to or to cause a processor to: output the reduced number of encoded bits, by transmitting the reduced number of encoded bits by a first communication device to a second communication device in a wireless communication network for example.

Embodiments related to such apparatus or non-transitory computer readable storage media may include any one or more of the following features, for example, which are also discussed elsewhere herein:
the encoded bits encoded by the polar code are in an order;
the subset comprises encoded bits that are non-consecutive in the order;
the subset is preceded by and followed by other encoded bits in the order;
the apparatus or a component thereof such as a rate matching module 1806 may be configured to, or programming may include instructions to or to cause a processor to: perform rate matching to reduce a number of the encoded bits in the subset;
the subset comprises one of a plurality of subsets of the encoded bits;
each subset of the plurality of subsets comprises a unique subset of fewer than all of the encoded bits and the plurality of subsets together comprising fewer than all of the encoded bits;
the apparatus or a component thereof such as the interleaver 1804 may be configured to, or programming may include instructions to or to cause a processor to: separately interleave the encoded bits in each subset of the plurality of subsets of the encoded bits;
the apparatus or a component thereof such as a rate matching module 1806 may be configured to, or programming may include instructions to or to cause a processor to: perform rate matching to reduce a number of the encoded bits in each of the subsets;
the apparatus or a component thereof such as the interleaver 1804 may be configured to, or programming may include instructions to or to cause a processor to: perform any one of: block interleaving and bit-reversed interleaving;
the apparatus or a component thereof such as the interleaver 1804 may be configured to, or programming may include instructions to or to cause a processor to: perform different types of interleaving for different subsets of a plurality of subsets;
the first set of bit indices, or more generally the bit indices, may comprise a first bit index on which a value of an input bit is placed instead of the value of the input bit being placed on a second bit index that is impacted by reducing the number of the encoded bits in the subset;
encoding may involve placing a value of an input bit on a bit index in the first set of bit indices instead of on a second bit index that is impacted by reducing the number of the encoded bits in the subset;
the bit indices further comprise a third set of bit indices comprising a first bit index on which a value of an input bit is placed instead of the value of the input bit being placed on a second bit index that is impacted by reducing the number of the encoded bits in the subset;
the second bit index corresponds to a bit index of an encoded bit that is reduced from the subset;
the first set of bit indices, or more generally the bit indices, may further comprise a third bit index on which a value of a further input bit is placed instead of the value of the further input bit being placed on a fourth bit index that corresponds to an index of one of the reduced number of the encoded bits in the subset;
the third set of bit indices further comprises a third bit index on which a value of a further input bit is placed instead of the value of the further input bit being placed on a fourth bit index that corresponds to an index of one of the reduced number of the encoded bits in the subset

In another apparatus embodiment, an apparatus includes an encoder such as 1802 and an interface. The encoder is for encoding input bits by a polar code to obtain a number of encoded bits, with the polar code comprising a plurality of bit indices for placing values of the input bits before encoding, and the bit indices comprising a first set of bit indices for the values of the input bits, and a second set of bit indices for a predetermined bit value. The encoded bits comprise a subset including fewer than all of the encoded bits. The subset is for reducing the number of the encoded bits. The bit indices comprise a respective first bit index on which a value of a respective input bit is placed instead of the value of the respective input bit being placed on a respective second bit index that corresponds to a bit index of each encoded bit in the subset. The interface is coupled to the encoder, for outputting the reduced number of the encoded bits.

An encoder such as 1802, according to another apparatus embodiment, is for obtaining an ordered sequence and encoding input bits by a polar code according to the ordered sequence, to obtain a number of encoded bits. The ordered sequence indicates a plurality of bit indices for the polar code in an order of rank for placing values of the input bits for the encoding by the polar code to obtain the number of encoded bits, and the bit indices comprise: a first set of bit indices of highest rank according to the ordered sequence, for placing the values of the input bits before encoding; and a second set of bit indices of lower rank than the highest rank according to the ordered sequence, for placing a predetermined bit value. The order of rank is for reducing the number of the encoded bits. Such an apparatus may also include an interface coupled to the encoder, for outputting the reduced number of the encoded bits.

In some embodiments, the apparatus or a component thereof such as the encoder 1802 may be configured to, or programming may include instructions to or to cause a processor to: obtain the ordered sequence by modifying a base sequence. The base sequence indicates the plurality of bit indices for the polar code in a base order of rank for placing the values of input bits for encoding by the polar code to obtain the number of encoded bits, and the base order of rank is for outputting the number of the encoded bits.

For a decoder-side or receiver-side apparatus or a computer program product comprising a non-transitory computer readable storage medium to support decoder-side or receiver-side operations, the apparatus may be configured to, or programming may include instructions to or to cause a processor to: receive a reduced number of encoded bits that have been encoded by a polar code, and decode the encoded bits to obtain decoded input bits. In another embodiment, an apparatus includes an interface for receiving a reduced number of encoded bits that have been encoded by a polar code, and a decoder coupled to the interface, for decoding the reduced number of encoded bits to obtain decoded input bits. The polar code comprises a plurality of bit indices for placing values of input bits, the bit indices comprising a first set of bit indices for the values of the input bits, and a second set of bit indices for a predetermined bit value. The received reduced number of encoded bits comprise encoded bits that remain after reduction in a number of the encoded bits in an interleaved subset of fewer than all of the encoded bits. The reduction in the number of encoded bits would have been after encoding of the input bits and before transmission of the reduced number of encoded bits that are received.

Embodiments related to such apparatus or non-transitory computer readable storage media may include any one or more of the following features, for example, which are also discussed elsewhere herein:
the apparatus or a component thereof such as an interface may be configured to, or programming may include instructions to or to cause a processor to: receive the reduced number of encoded bits from a first communication device by a second communication device in a wireless communication network;
the encoded bits encoded by the polar code are in an order;
the subset comprises encoded bits that are non-consecutive in the order;
the subset is preceded by and followed by other encoded bits in the order;
the reduction in the number of the encoded bits in the interleaved subset comprised rate matching, by a rate matching module 1806 for example, before the reduced number of encoded bits were transmitted;
the subset comprises one of a plurality of subsets of the encoded bits;
each subset of the plurality of subsets comprises a unique subset of fewer than all of the encoded bits and the plurality of subsets together comprise fewer than all of the encoded bits;
the encoded bits in each subset of the plurality of subsets are separately interleaved prior to reduction in a number of the encoded bits in each of the subsets;
the encoded bits in each subset of the plurality of subsets of the encoded bits are separately interleaved prior to the rate matching for reduction in a number of the encoded bits in each of the subsets;
the subset is interleaved by any one of: block interleaving and bit-reversed interleaving;
in an embodiment with a plurality of subsets, each subset is interleaved by any one of: block interleaving and bit-reversed interleaving;
in another embodiment with a plurality of subsets, the encoded bits in different subsets of the plurality of subsets are separately interleaved by different types of interleaving;
the first set of bit indices, or more generally the bit indices comprising the polar code, comprise a first bit index on which a value of an input bit was placed instead of the value of the input bit being placed on a second bit index that is impacted by the reduction in the number of the encoded bits;
the bit indices further comprise a third set of bit indices comprising a first bit index on which a value of an input bit was placed instead of the value of the input bit being placed on a second bit index that is impacted by the reduction in the number of the encoded bits;
the second bit index corresponds to a bit index of an encoded bit that was reduced from the subset;
the first set of bit indices, or more generally the bit indices comprising the polar code, further comprises a third bit index on which a value of a further input bit was placed instead of the value of the further input bit being placed on a fourth bit index that corresponds to an index of one of the reduced number of the encoded bits in the subset;
the third set of bit indices further comprises a third bit index on which a value of a further input bit was placed instead of the value of the further input bit being placed on a fourth bit index that corresponds to an index of one of the reduced number of the encoded bits in the subset.

In another apparatus embodiment, an apparatus includes an interface and a decoder. The interface is for receiving a reduced number of encoded bits encoded by a polar code, and the decoder is coupled to the interface, for decoding the reduced number of encoded bits to obtain decoded input bits. Programming may include instructions to or to cause a processor to receive a reduced number of encoded bits encoded by a polar code, and to decode the reduced number of encoded bits to obtain decoded input bits. In both of these examples, the polar code may comprise a plurality of bit indices for placing values of input bits, with the bit indices comprising a first set of bit indices for the values of the input bits, and a second set of bit indices for a predetermined bit value. The received reduced number of encoded bits comprise bits of the encoded bits that remain after reduction in a number of the encoded bits in a subset of the encoded bits that includes fewer than all of the encoded bits. The bit indices comprise a respective first bit index on which a value of a respective input bit was placed instead of the value of the respective input bit being placed on a respective second bit index that corresponds to a bit index of each encoded bit in the subset.

An interface according to another apparatus embodiment is for receiving a reduced number of encoded bits encoded by a polar code. Such an apparatus may also include a decoder coupled to the interface, for decoding the reduced number of encoded bits to obtain decoded input bits. In a programming embodiment, programming may include instructions to or to cause a processor to receive a reduced number of encoded bits encoded by a polar code, and to decode the reduced number of encoded bits to obtain decoded input bits. In either of these embodiments, the polar code may comprise a plurality of bit indices for placing values of input bits for encoding to obtain a number of encoded bits, with the bit indices comprising: a first set of bit indices of highest rank according to an ordered sequence, for placing values of the input bits before encoding; and a second set of bit indices of lower rank than the highest rank according to the ordered sequence, for placing a predetermined bit value. The ordered sequence indicates the plurality of bit indices in an order of rank for placing the values of the input bits, and the order of rank is for reducing the number of the encoded bits to the reduced number of the encoded bits.

The ordered sequence may have been obtained by modifying a base sequence that indicates the plurality of bit indices for the polar code in a base order of rank for placing the values of input bits for encoding by the polar code to obtain the number of encoded bits. The base order of rank is for outputting the number of the encoded bits.

Apparatus embodiments are not in any way restricted to single devices. A system, for example, may include a first communication device and a second communication device. The first communication device may be configured to transmit a reduced number of encoded bits that have been encoded by a polar code, and the second communication device may be configured to receive the reduced number of the encoded bits from the first communication device, and to decode the reduced number of the encoded bits to obtain decoded input bits. As in other embodiments, the polar code may comprise a plurality of bit indices for placing values of input bits, with the bit indices comprising a first set of bit indices for the values of the input bits and a second set of bit indices for a predetermined bit value, and the reduced number of encoded bits comprising bits of the encoded bits that remain after reduction in a number of the encoded bits in an interleaved subset of fewer than all of the encoded bits.

The first communication device in a system may also or instead implement, provide, or support other encode-side or transmit-side features disclosed herein, and similarly the second communication device in a system may also or instead implement, provide, or support other decode-side or receive-side features disclosed herein.

More generally, other features disclosed herein may also or instead be provided in method, apparatus, and/or system embodiments.

Embodiments disclosed herein encompass various aspects of polar coding, including encoding and decoding.

Disclosed embodiments may provide a fundamental upgrade of polar codes, and may make polar codes applicable for a much wider set of scenarios.

For example, disclosed embodiments may be implemented as part of a channel coding scheme, and may thus be applicable wherever channel coding is used. This covers a very wide range of scenarios. The flexibility provided by embodiments disclosed herein may help make the associated channel coding scheme particularly suitable for wireless communications.

Possible product deployments, in or in conjunction with which embodiments may be implemented, include network devices such as base stations, access devices such as UEs, robots, sensors, cars, drones, and satellites. Service deployment examples include enhanced mobile broadband (eMBB), ultra-reliable low latency communications (URLLC), massive machine type communications (mMTC)/Internet of things (IoT), and vehicular and industry scenarios. Network deployment examples include 5G+, 6G, WiFi, non-terrestrial networks (NTNs), optical networks, distributed networks, and self-organized networks. These are illustrative and non-limiting examples, and other deployments, implementations, or applications are possible.

Potential advantages of embodiments disclosed herein include providing low-complexity and rate-compatible polar codes.

Partially-interleaved puncturing as disclosed herein, for example, may help avoid catastrophic performance loss, and also provide low-complexity puncture-only rate matching. Complex online calculations (DE/GA) involved with some existing approaches are no longer required, and complicated hybrid puncturing and shortening can also be avoided.

Information bit recycling as disclosed herein may also help avoid catastrophic performance loss caused by transmitting over zero-capacity subchannels.

Disclosed embodiments also encompass parameterized description, which can be advantageous in providing a concise description to efficiently define fine-grained partial interleaving, for example.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

1. A method comprising:
encoding input bits by a polar code to obtain a number of encoded bits, the polar code comprising a plurality of bit indices for placing values of the input bits before encoding, the plurality of bit indices comprising a first set of bit indices for the values of the input bits and a second set of bit indices for a predetermined bit value;
interleaving a subset of the encoded bits, the subset including fewer than all of the encoded bits, the subset for reducing the number of the encoded bits; and
outputting the reduced number of the encoded bits.

2. The method of any claim 1,
wherein the subset comprises one of a plurality of subsets of the encoded bits, each subset of the plurality of subsets comprising a respective unique subset of fewer than all of the encoded bits and the plurality of subsets together being fewer than all of the encoded bits, and
wherein the interleaving comprises separately interleaving the encoded bits in each subset of the plurality of subsets of the encoded bits, including interleaving the subset.

3. The method of claim 2, further comprising:
performing rate matching to reduce a first number of encoded bits in the subset,
wherein the performing comprises performing the rate matching on the encoded bits to reduce a respective number of respective encoded bits in each of the plurality of subsets.

4. The method of claim 1, wherein the first set of bit indices comprises a first bit index on which a value of an input bit is placed instead of the value of the input bit being placed on a second bit index that is impacted by reducing a first number of encoded bits in the subset.

5. The method of claim 1, wherein the plurality of bit indices further comprises a third set of bit indices comprising a first bit index on which a value of an input bit is placed instead of the value of the input bit being placed on a second bit index that is impacted by reducing a first number of encoded bits in the subset.

6. A method comprising:
receiving a reduced number of encoded bits encoded by a polar code, the polar code comprising a plurality of bit indices for placing values of input bits, the plurality of bit indices comprising a first set of bit indices for the values of the input bits, and a second set of bit indices for a predetermined bit value,
the reduced number of encoded bits comprising bits of the encoded bits that remain after reduction in a number of the encoded bits in an interleaved subset of fewer than all of the encoded bits; and
decoding the reduced number of encoded bits to obtain decoded input bits.

7. The method of claim 6,
wherein the interleaved subset comprises one of a plurality of subsets of the encoded bits, each subset of the plurality of subsets comprising a respective unique subset of fewer than all of the encoded bits and the plurality of subsets together being fewer than all of the encoded bits, and
wherein respective encoded bits in each subset of the plurality of subsets of the encoded bits, including the subset, are separately interleaved prior to reduction in a respective number of encoded bits in each of the plurality of subsets.

8. The method of claim 7,
wherein the reduction in the number of the encoded bits in the interleaved subset comprises rate matching.

9. The method of claim 6, wherein the first set of bit indices comprises a first bit index on which a value of an input bit was placed instead of the value of the input bit being placed on a second bit index that is impacted by the reduction in the number of the encoded bits.

10. The method of claim 6, wherein the plurality of bit indices further comprises a third set of bit indices comprising a first bit index on which a value of an input bit was placed instead of the value of the input bit being placed on a second bit index that is impacted by the reduction in the number of the encoded bits.

11. An apparatus comprising:
an encoder configured to encode input bits by a polar code to obtain a number of encoded bits, the polar code comprising a plurality of bit indices for placing values of the input bits before encoding, the plurality of bit indices comprising a first set of bit indices for the values of the input bits, and a second set of bit indices for a predetermined bit value;
an interleaver coupled to the encoder, configured to interleave a subset of the encoded bits, the subset including fewer than all of the encoded bits, the subset for reducing the number of the encoded bits; and
an interface coupled to the encoder, configured to output the reduced number of the encoded bits.

12. The apparatus of claim 11,
wherein the subset comprises one of a plurality of subsets of the encoded bits, each subset of the plurality of subsets comprising a respective unique subset of fewer than all of the encoded bits and the plurality of subsets together being fewer than all of the encoded bits, and
wherein the interleaver is configured to separately interleave the encoded bits in each subset of the plurality of subsets of the encoded bits, including interleaving the subset.

13. The apparatus of claim 12, further comprising a rate matcher configured to:
perform rate matching to reduce a first number of the encoded bits in the subset,
wherein performing the rate matching comprises performing the rate matching on the encoded bits to reduce a respective number of respective encoded bits in each of the plurality of subsets.

14. The apparatus of claim 11, wherein the first set of bit indices comprises a first bit index on which a value of an input bit is placed instead of the value of the input bit being placed on a second bit index that is impacted by reducing the number of the encoded bits in the subset.

15. The apparatus of claim 11, wherein the plurality of bit indices further comprises a third set of bit indices comprising a first bit index on which a value of an input bit is placed instead of the value of the input bit being placed on a second bit index that is impacted by reducing a first number of encoded bits in the subset.

16. An apparatus comprising:
an interface configured to receive a reduced number of encoded bits encoded by a polar code, the polar code comprising a plurality of bit indices for placing values of input bits, the plurality of bit indices comprising a first set of bit indices for the values of the input bits, and a second set of bit indices for a predetermined bit value;
the reduced number of encoded bits comprising bits of the encoded bits that remain after reduction in a number of the encoded bits in an interleaved subset of fewer than all of the encoded bits; and
a decoder coupled to the interface, configured to decode the reduced number of encoded bits to obtain decoded input bits.

17. The apparatus of claim 16,
wherein the interleaved subset comprises one of a plurality of subsets of the encoded bits, each subset of the plurality of subsets comprising a respective unique subset of fewer than all of the encoded bits and the plurality of subsets together being fewer than all of the encoded bits, and
wherein respective encoded bits in each subset of the plurality of subsets of the encoded bits, including the subset, are separately interleaved prior to reduction in a respective number of encoded bits in each of the plurality of subsets.

18. The apparatus of claim 17,
wherein the reduction in the number of the encoded bits in the interleaved subset comprises rate matching.

19. The apparatus of claim 16, wherein the first set of bit indices comprises a first bit index on which a value of an input bit was placed instead of the value of the input bit being placed on a second bit index that is impacted by the reduction in the number of the encoded bits.

20. The apparatus of claim 16, wherein the plurality of bit indices further comprises a third set of bit indices comprising a first bit index on which a value of an input bit was placed instead of the value of the input bit being placed on a second bit index that is impacted by the reduction in the number of the encoded bits.
